(19) United States
(12) Patent Application Publication
(10) Pub. No.: US 2025/0271265 A1
(43) Pub. Date: Aug. 28, 2025

(54) WEARABLE ELECTRONIC DEVICE AND OPERATING METHOD THEREFOR

(71) Applicant: Samsung Electronics Co., Ltd., Suwon-si (KR)

(72) Inventor: Taekeun KIM, Suwon-si (KR)

(21) Appl. No.: 19/209,239

(22) Filed: May 15, 2025

Related U.S. Application Data
(63) Continuation of application No. PCT/KR2023/018555, filed on Nov. 17, 2023.

(30) Foreign Application Priority Data
Nov. 18, 2022 (KR) 10-2022-0155307
Mar. 24, 2023 (KR) 10-2023-0038703

(51) Int. Cl. G01C 17/38; G01C 17/30

(52) U.S. Cl. CPC G01C 17/38; G01C 17/30

(57) ABSTRACT

A wearable electronic device is provided. The wearable electronic device includes a display, a sensor configured to detect geomagnetism and acquire geomagnetic data, memory storing one or more computer programs, and one or more processors communicatively coupled to the display, the sensor, and memory, wherein the one or more computer programs include computer-executable instructions that, when executed by the one or more processors individually or collectively, cause the wearable electronic device to acquire an azimuth angle on the based on geomagnetic data, acquire a plurality of offsets based on the geomagnetic data when geomagnetic calibration is executed, acquire a reference azimuth angle based on the plurality of offsets, acquire an azimuth angle error based on a uniformity of the plurality of offsets, acquire a new reference azimuth angle by compensating for the azimuth angle error with the reference azimuth angle, and update the new reference azimuth angle in the memory.

### CROSS-REFERENCE TO RELATED APPLICATION(S)

This application is a continuation application, claiming priority under 35 U.S.C. § 365(c), of an International application No. PCT/KR2023/018555, filed on Nov. 17, 2023, which is based on and claims the benefit of a Korean patent application number 10-2022-0155307, filed on Nov. 18, 2022, in the Korean Intellectual Property Office, and of a Korean patent application number 10-2023-0038703, filed on Mar. 24, 2023, in the Korean Intellectual Property Office, the disclosure of each of which is incorporated by reference herein in its entirety.

### BACKGROUND

### 1. Field

The disclosure relates to a wearable electronic device and a method of operating the same, capable of displaying a compensated azimuth angle error caused by a geomagnetic disturbance in an environment where a geomagnetic disturbance (or magnetic disturbance) occurs.

### 2. Description of Related Art

With the development of electronic technology, electronic devices with a global positioning system (GPS) and a compass function are being developed. In order for electronic devices to perform a GPS and a compass function, they need to calculate an azimuth angle. To calculate the azimuth angle, the electronic device may be equipped with a gyro sensor or a geomagnetic sensor. A gyro sensor is a sensor that detects rotational angular velocity by measuring the Coriolis Force. When using a gyro sensor, the acceleration is measured and integrated to calculate the velocity, and then a double integration is performed to acquire the displacement information. A geomagnetic sensor is a sensor that detects geomagnetism by measuring the voltage value induced by geomagnetism using a flux-gate or the like. Geomagnetic sensors may be implemented as 2-axis or 3-axis. Since the geomagnetic output value from a 2-axis or 3-axis geomagnetic sensor depends on the magnitude of the ambient magnetic field, normalization may be performed to map the geomagnetic output value within a predetermined range. In the case that a geomagnetic sensor is used, the azimuth angle may be measured by performing a calibration. Geomagnetic data may be acquired through measuring the geomagnetic field at regular intervals by rotating the electronic device to a figure of 8 (or 360 degrees) at a point. When the acquired geomagnetic data is graphed, it is elliptical in shape, and hard-iron and soft-iron operations may be performed. After performing the calibration, an azimuth angle may be acquired (e.g., generated) based on the acquired geomagnetic data.

The above information is presented as background information only to assist with an understanding of the disclosure. No determination has been made, and no assertion is made, as to whether any of the above might be applicable as prior art with regard to the disclosure.

### SUMMARY

When moving an electronic device (e.g., smartphone, wearable electronics, smartwatch) in a figure of 8 (or a 360-degree rotation), the center point of a sphere can be acquired from ambient magnetic data to provide compass function. When calibration is performed in an environment where magnetic disturbances may occur, the magnetic data used to acquire the center point of the virtual sphere may contain a noise component. Estimating the center point of the sphere from noisy magnetic data may result in an error in the azimuth angle information (e.g., from about 30 degrees to about 100 degrees). A user may not be able to intuitively determine whether the azimuth angle information of the compass function provided by the electronic device is accurate and whether there is an error (e.g., about 30 degrees to about 100 degrees) in the azimuth angle information. As a result, the compass function of the electronic device may not be provided normally in an environment where magnetic disturbances occur.

Aspects of the disclosure are to address at least the above-mentioned problems and/or disadvantages and to provide at least the advantages described below. Accordingly, an aspect of the disclosure is to provide an electronic device and a method of operation thereof that can acquire highly reliable magnetic information to provide more accurate compass information in an environment where magnetic disturbances occur because of the electronic device moving from indoors to outdoors.

Another aspect of the disclosure is to provide an electronic device and a method of operation thereof that can acquire highly reliable magnetic information to provide more accurate compass information in an environment where magnetic disturbances occur because of the electronic device moving from outdoors to indoors.

Another aspect of the disclosure is to provide an electronic device and a method of operation thereof that can acquire highly reliable magnetic information to provide more accurate compass information in an environment where magnetic disturbances occur because of the electronic device being moved from outdoors (or indoors) to an interior of a vehicle.

Another aspect of the disclosure is to provide an electronic device and a method of operation thereof that can acquire highly reliable magnetic information to provide more accurate compass information in an environment where magnetic disturbances occur because of the movement of an electronic device from an interior of a vehicle to an exterior of the vehicle.

Another aspect of the disclosure is to provide an electronic device and an operation method thereof that can determine the reliability of the acquired correction data when the correction function of magnetic data is performed in an environment with magnetic disturbances.

Another aspect of the disclosure is to provide an electronic device and a method of operation thereof that can determine a level of magnetic disturbance and acquire reliable magnetic data in a magnetically disturbed environment, such as indoors or inside a vehicle, where magnetic disturbance occurs.

Another aspect of the disclosure is to provide an electronic device and a method of operation thereof that can display an error in an azimuth angle when providing a compass function based on reliable magnetic data, and display the error-corrected azimuth angle.

Additional aspects will be set forth in in part in the description which follows and, in part, will be apparent from the description, or may be learned by practice of the presented embodiments.

In accordance with an aspect of the disclosure, a wearable electronic device is provided. The wearable device includes a display, a sensor configured to detect geomagnetism and acquire geomagnetic data, memory storing one or more computer programs, and one or more processors communicatively coupled to the display, the sensor, and the memory, wherein the one or more computer programs include computer-executable instructions that, when executed by the one or more processors individually or collectively, cause the wearable electronic device to acquire an azimuth angle based on the geomagnetic data, acquire a plurality of offsets based on the geomagnetic data when geomagnetic calibration is executed, acquire a reference azimuth angle based on the plurality of offsets, acquire an azimuth angle error based on a uniformity of the plurality of offsets, acquire a new reference azimuth angle by compensating for the azimuth angle error with the reference azimuth angle, and update the new reference azimuth angle in the memory.

In accordance with another aspect of the disclosure, a method performed by an electronic device including a sensor configured to detect geomagnetism is provided. The method includes acquiring geomagnetic data when executing of the geomagnetic calibration, acquiring a plurality of offsets based on the geomagnetic data, acquiring a reference azimuth angle based on the plurality of offsets, acquiring an azimuth angle error based on a uniformity of the plurality of offsets, acquiring a new reference azimuth angle by compensating for the azimuth angle error with the reference azimuth angle, and updating the new reference azimuth angle in memory of the electronic device storing one or more computer programs.

In accordance with another aspect of the disclosure, one or more non-transitory computer-readable recording media storing one or more computer programs including computer-executable instructions that, when executed by one or more processors of an electronic device including a sensor configured to detect geomagnetism individually or collectively, cause the electronic device to perform operations are provided. The operations include acquiring geomagnetic data when executing geomagnetic calibration, acquiring a plurality of offsets based on the geomagnetic data, acquiring a reference azimuth angle based on the plurality of offsets, and acquiring an azimuth angle error based on a uniformity of the plurality of offsets, acquiring a new reference azimuth angle by compensating for the azimuth angle error with the reference azimuth angle, and updating the new reference azimuth angle in the memory.

An electronic device and a method of operation thereof according to an embodiment of the disclosure induces magnetic data correction more naturally and provide accurate azimuth angle information to a user even in magnetic disturbance environments.

An electronic device and a method of operation thereof according to an embodiment of the disclosure determines a level of error in the azimuth angle information currently being used and provide the level of error in the azimuth angle information to a user.

An electronic device and a method of operation thereof according to an embodiment of the disclosure relatively improves the accuracy of an azimuth angle in an environment (outdoor, indoor, vehicle) where magnetic disturbances occur.

An electronic device and a method of operation thereof according to an embodiment of the disclosure selectively utilizes a precision error acquired in an environment with low magnetic disturbance by comparing a previous (e.g., existing) precision error with a newly acquired new precision error. The geomagnetic data based on the precision error acquired in the low magnetic disturbance environment is used to update the azimuth angle to relatively improve the accuracy of the azimuth angle. Furthermore, the accuracy of the azimuth angle is relatively improved by optionally applying a gyro weighting along with the precision error.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIGS. 2A and 2B are front and rear views of an unfolded state of an electronic device according to various embodiments of the disclosure;

FIGS. 2C and 2D are front and rear views of a folded state of an electronic device according to various embodiments of the disclosure;

FIG. 3A is a perspective view of a first surface (e.g., a front surface) of an electronic device according to an embodiment of the disclosure;

FIG. 3B is a perspective view of a second surface (e.g., a rear surface) of an electronic device according to an embodiment of the disclosure;

FIG. 4A is a perspective view of a first surface (e.g., a front surface) of an electronic device according to an embodiment of the disclosure;

FIG. 4B is a perspective view of a second surface (e.g., a rear surface) of an electronic device according to an embodiment of the disclosure;

FIG. 5 is a block diagram illustrating a configuration of an electronic device according to an embodiment of the disclosure;

FIG. 6 is a diagram illustrating components of ambient magnetic force for providing azimuth angle information in an electronic device according to an embodiment of the disclosure;

FIG. 7 is a diagram illustrating an operation method of a geomagnetic sensor according to an embodiment of the disclosure;

FIG. 8 is a flowchart illustrating a method performed by an electronic device according to an embodiment of the disclosure;

FIG. 9 is a diagram illustrating an offset value acquired from a geomagnetic data set according to an embodiment of the disclosure;

FIG. 10 is a diagram illustrating updating an accuracy level of azimuth angle according to an embodiment of the disclosure;

FIG. 11 is a diagram illustrating offset values of an x-axis stored in a buffer (e.g., memory) by performing a calibration of a geomagnetic sensor according to an embodiment of the disclosure;

FIG. 12 is a diagram illustrating offset values of a y-axis stored in a buffer (e.g., memory) by performing a calibration of a geomagnetic sensor according to an embodiment of the disclosure;

FIG. 13 is a diagram illustrating offset values of a z-axis stored in a buffer (e.g., memory) by performing a calibration of a geomagnetic sensor according to an embodiment of the disclosure;

FIG. 14 is a diagram illustrating calculating precision error on a basis of offset values of geomagnetic data according to an embodiment of the disclosure;

FIG. 15 is a diagram illustrating updating an accuracy level by comparing a relationship between an offset value stored in a buffer and a median value and a precision error according to an embodiment of the disclosure;

FIGS. 16A, 16B, 16C, and 16D are diagrams illustrating examples of simulating azimuth angle error according to a precision error level according to various embodiments of the disclosure;

FIG. 17 is a diagram illustrating calculating azimuth angle based on pure magnetic data according to an embodiment of the disclosure;

FIG. 18 is a diagram illustrating adjusting an azimuth angle error based on a precision error according to an embodiment of the disclosure;

FIGS. 19 and 20 are flowcharts illustrating a method performed by an electronic device according to various embodiments of the disclosure;

FIG. 21 is a diagram illustrating dynamically displaying azimuth angle error according to a precision error level according to an embodiment of the disclosure; and

FIG. 22 is a diagram illustrating calibration result values according to precision error and confidence level at each stage according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and configurations may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

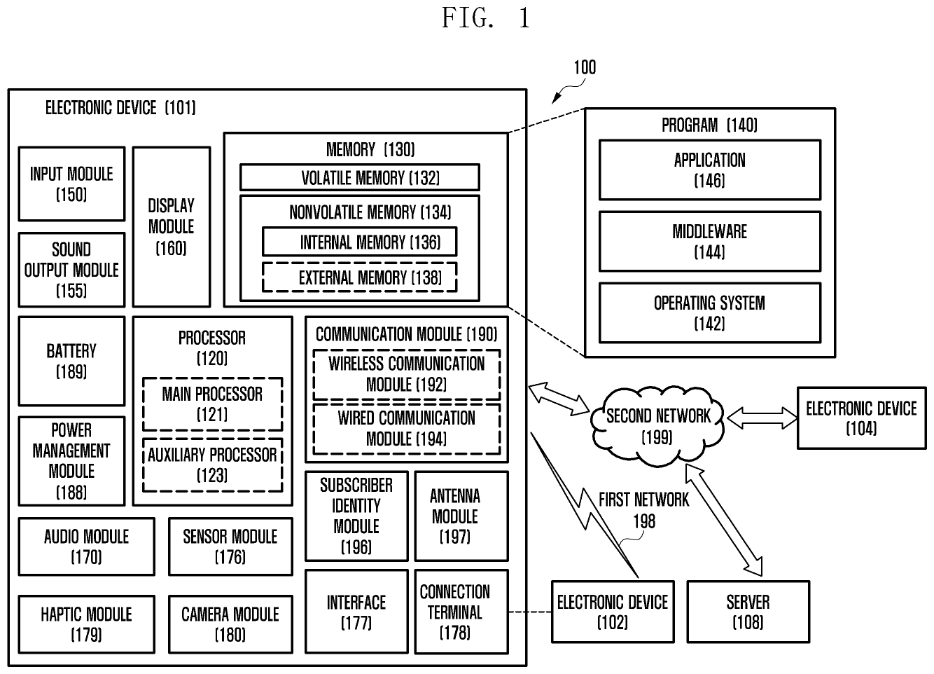

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

According to one embodiment of the disclosure, the display module 160 may include a flexible display configured to be foldable or unfoldable.

According to one embodiment of the disclosure, the display module 160 may include a flexible display that is disposed in in a slidable manner and provides a screen (e.g., a display screen).

According to one embodiment of the disclosure, the display module 160 may also be referred to as a stretchable display, an expandable display, or a slide-out display.

According to one embodiment of the disclosure, the display module 160 may include a bar type or plate type display.

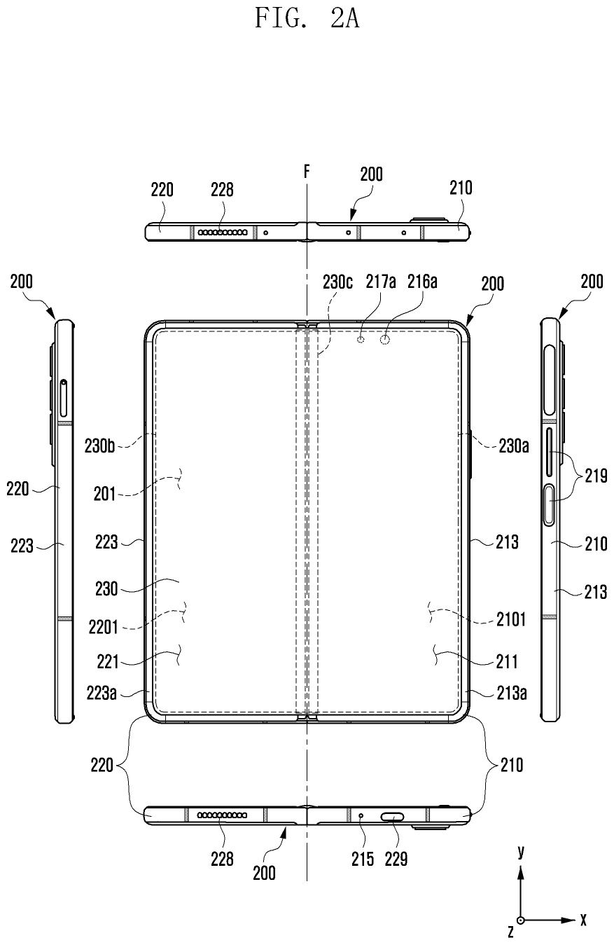

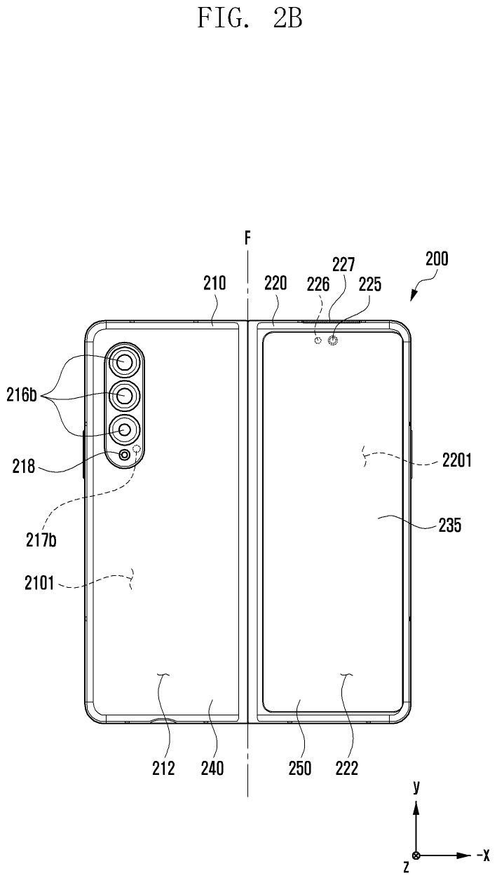

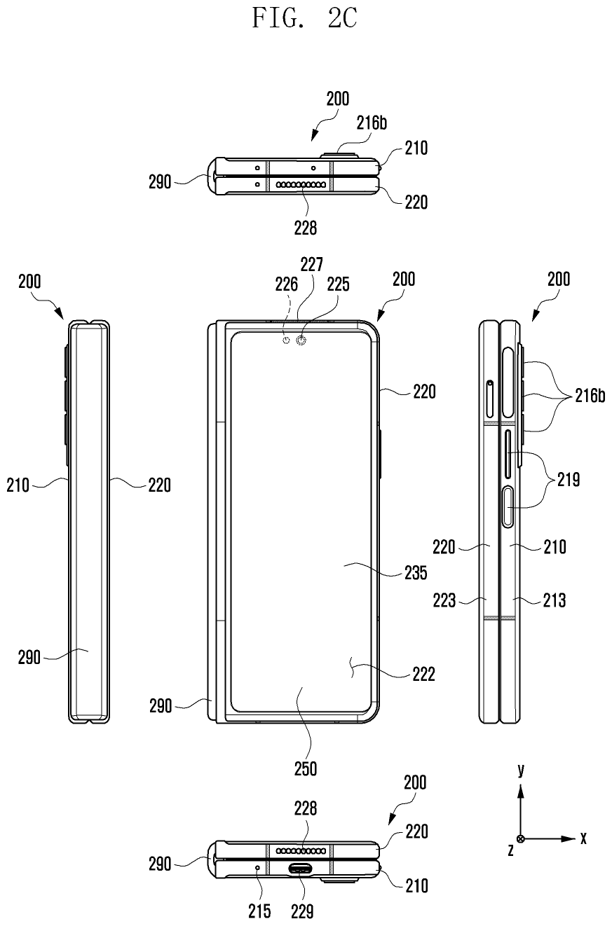

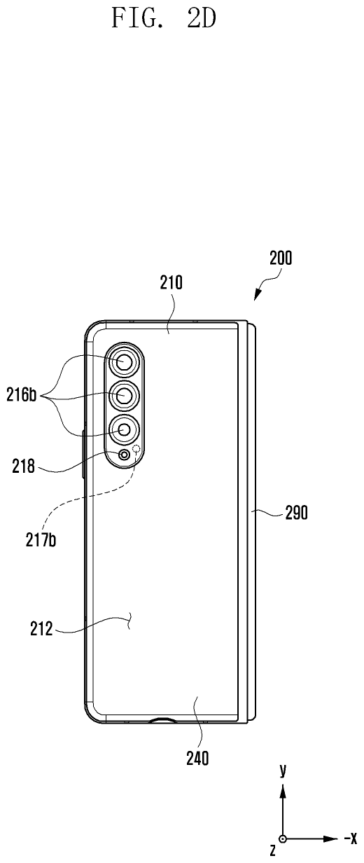

FIGS. 2A and 2B are front and rear views of an unfolded state of an electronic device according to various embodiments of the disclosure.

FIGS. 2C and 2D are front and rear views of a folded state of an electronic device according to various embodiments of the disclosure.

Referring to FIGS. 2A, 2B, 2C and 2D, an electronic device 200 (e.g., the electronic device 101 of FIG. 1) according to one embodiment of the disclosure may comprise: a pair of housings 210 and 220 (e.g., a foldable housing structure) rotatably coupled about a folding axis F through at least one hinge device (e.g., a hinge module or hinge structure) foldable relative to each other; a first display 230 (e.g., a flexible display, a foldable display, or a main display) disposed through the pair of housings 210 and 220; and/or a second display 235 (e.g., a sub-display) disposed through the second housing 220.

According to one embodiment of the disclosure, at least a portion of at least one hinge device may be disposed so as not to be visible from the outside through the first housing 210 and the second housing 220 and may be disposed so as not to be visible from the outside through a hinge housing 290 (e.g., a hinge cover) that covers the foldable portion when unfolded. In this document, a surface on which the first display 230 is disposed may be defined as a front surface of the electronic device 200, and a surface opposite to the front surface may be defined as a rear surface of the electronic device 200. Additionally, a surface surrounding a space between the front surface and the rear surface may be defined as a side surface of the electronic device 200.

According to one embodiment of the disclosure, a pair of housings 210 and 220 may include a first housing 210 and a second housing 220 that are foldably disposed relative to each other through at least one hinge device.

According to one embodiment of the disclosure, the pair of housings 210 and 220 are not limited to the shapes and combinations illustrated in FIGS. 2A to 2D and may be implemented by other shapes or combinations and/or couplings of parts.

According to one embodiment of the disclosure, the first housing 210 and the second housing 220 may be disposed on both sides with respect to the folding axis F, have an overall symmetrical shape with respect to the folding axis F, and be folded to match each other.

According to one embodiment of the disclosure, the first housing 210 and the second housing 220 may be folded asymmetrically with respect to the folding axis F.

According to one embodiment of the disclosure, the angle or distance between the first housing 210 and the second housing 220 may be different depending on whether the electronic device 200 is in an unfolded state, a folded state, or an intermediate state.

According to one embodiment of the disclosure, the first housing 210 may be connected to at least one hinge device in the unfolded state of the electronic device 200. The first housing 210 may include a first surface 211 disposed to face the front surface of the electronic device 200, a second surface 212 facing in an opposite direction to the first surface 211, and/or a first lateral member 213 surrounding at least a portion of a first space 2101 between the first surface 211 and the second surface 212.

According to one embodiment of the disclosure, the second housing 220 may be connected to at least one hinge device in the unfolded state of the electronic device 200. The second housing 220 may include a third surface 221 disposed to face the front of the electronic device 200, a fourth surface 222 facing in an opposite direction of the third surface 221, and/or a second lateral member 223 surrounding at least a portion of a second space 2201 between the third surface 221 and the fourth surface 222.

According to one embodiment of the disclosure, the first surface 211 may face substantially the same direction as the third side 221 in the unfolded state and may be at least partially facing the third side 221 in the folded state.

According to one embodiment of the disclosure, the electronic device 200 may include a recess 201 formed to accommodate a first display 230 through a structural coupling of a first housing 210 and a second housing 220.

According to one embodiment of the disclosure, the recess 201 may have substantially the same size as the first display 230.

According to one embodiment of the disclosure, the first housing 210 may be coupled with the first lateral member 213 when the first display 230 is viewed from above. The first housing 210 may include a first protection frame 213a (e.g., a first decoration member) that overlaps with the edge of the first display 230 to cover the edge of the first display 230 so that it is not visible from the outside.

According to one embodiment of the disclosure, the first protection frame 213a may be formed integrally with the first lateral member 213.

According to one embodiment of the disclosure, the second housing 220 may be coupled with the second lateral member 223 when the first display 230 is viewed from above. The second housing 220 may include a second protection frame 223a that overlaps with the edge of the first display 230 to cover the edge of the first display 230 so that it is not visible from the outside.

According to one embodiment of the disclosure, the second protection frame 223a may be formed integrally with the second lateral member 223. In one embodiment of the disclosure, the first protection frame 213a and the second protection frame 223a may be omitted.

According to one embodiment of the disclosure, a hinge housing 290 (e.g., a hinge cover) may be disposed between the first housing 210 and the second housing 220. The hinge housing 290 may be disposed to cover at least a portion of one hinge device (e.g., at least one hinge module).

According to one embodiment of the disclosure, the hinge housing 290 may be covered by a portion of the first housing 210 and the second housing 220 or exposed to the outside, depending on the unfolded state, the folded state, or the intermediate state of the electronic device 200. For example, when the electronic device 200 is in the unfolded state, at least a portion of the hinge housing 290 may be covered by the first housing 210 and the second housing 220 and may be disposed to be substantially invisible from the outside.

According to one embodiment of the disclosure, when the electronic device 200 is in a folded state, at least a portion of the hinge housing 290 may be disposed to be visible from the outside between the first housing 210 and the second housing 220.

According to one embodiment of the disclosure, when the first housing 210 and the second housing 220 are in an intermediate state where they are folded with a certain angle, the hinge housing 290 may be disposed between the first housing 210 and the second housing 220 to be at least partially visible from the outside of the electronic device 200. For example, the area where the hinge housing 290 is exposed to the outside in an intermediate state may be less than when it is completely folded. According to an embodiment of the disclosure, the hinge housing 290 may include a curved surface.

According to one embodiment of the disclosure, when the electronic device 200 is in an unfolded state (e.g., the state of FIGS. 2A and 2B), the first housing 210 and the second housing 220 form an angle of about 180 degrees, and the first area 230a, the second area 230b, and the folding area 230c of the first display 230 may form substantially the same plane. The first area 230a, the second area 230b, and the folding area 230c of the first display 230 may be disposed to face substantially the same direction (e.g., z-axis direction). In one embodiment of the disclosure, when the electronic device 200 is in an unfolded state, the first housing 210 may be rotated at an angle of about 360 degrees with respect to the second housing 220 so that the second surface 212 and the fourth surface 222 face each other and may be folded in the opposite direction (e.g., out folding method).

According to one embodiment of the disclosure, when the electronic device 200 is in a folded state (e.g., the state of FIGS. 2C and 2D), the first surface 211 of the first housing 210 and the third surface 221 of the second housing 220 may be disposed to face each other. In this case, the first area 230a and the second area 230b of the first display 230 may be disposed to face each other while forming a narrow angle (e.g., in a range of about 0 degrees to about 10 degrees) with each other through the folding area 230c. According to one embodiment of the disclosure, at least a portion of the folding area 230c may be deformed into a curved shape having a predetermined curvature.

According to one embodiment of the disclosure, when the electronic device 200 is in an intermediate state, the first housing 210 and the second housing 220 may be disposed at a certain angle with respect to each other. In this case, the first area 230a and the second area 230b of the first display 230 may form an angle that is larger than the folded state and smaller than the unfolded state, and the curvature of the folding area 230c may be smaller than the folded state and larger than the unfolded state. In one embodiment of the disclosure, the first housing 210 and the second housing 220 may form an angle that can stop at a certain folding angle between the folded state and the unfolded state through at least one hinge device (e.g., free stop function). In one embodiment of the disclosure, the first housing 210 and the second housing 220 may be operated continuously while being pressurized in an unfolding or folding direction based on a specified inflection angle through at least one hinge device.

According to one embodiment of the disclosure, the electronic device 200 may include at least one of a display 230 and 235, an input device 215, audio output devices 227 and 228, sensor modules 217a, 217b, and 226, camera modules 216a, 216b, and 225, a key input device 219, an indicator (not shown), or a connector port 229 disposed in the first housing 210 and/or the second housing 220. In one embodiment of the disclosure, the electronic device 200 may omit at least one of the components or may additionally include at least one other component.

According to one embodiment of the disclosure, at least one display 230 and 235 may include a first display 230 (e.g., a flexible display) that is disposed to be supported by a third surface 221 of a second housing 220 through at least one hinge device from a first surface 211 of the first housing 210, and a second display 235 that is disposed to be at least partially visible from the outside through a fourth surface 222 in an inner space of the second housing 220.

According to one embodiment of the disclosure, the second display 235 may be disposed to be visible from the outside through the second surface 212 in the inner space of the first housing 210.

According to one embodiment of the disclosure, the first display 230 may be primarily used in the unfolded state of the electronic device 200. The second display 235 may be primarily used in the folded state of the electronic device 200.

According to one embodiment of the disclosure, the electronic device 200 may control the first display 230 and/or the second display 235 to be usable based on the folding angles of the first housing 210 and the second housing 220 in an intermediate state.

According to one embodiment of the disclosure, the first display 230 may be disposed in an accommodation space formed by a pair of housings 210 and 220. For example, the first display 230 may be disposed in a recess 201 formed by a pair of housings 210 and 220 and, when unfolded, may be disposed to occupy substantially most of the front surface of the electronic device 200. According to one embodiment of the disclosure, the first display 230 may include a flexible display in which at least a portion of the display may be transformed into a flat or curved surface.

According to one embodiment of the disclosure, the first display 230 may include a first area 230a facing the first housing 210 and a second area 230b facing the second housing 220. According to one embodiment of the disclosure, the first display 230 may include a folding area 230c including a portion of the first area 230a and a portion of the second area 230b based on the folding axis F.

According to one embodiment of the disclosure, at least a portion of the folding area 230c may include an area corresponding to at least one hinge device.

According to one embodiment of the disclosure, the area division of the first display 230 is merely a physical division by a pair of housings 210 and 220 and at least one hinge device, and in reality, the first display 230 may be displayed as a seamless full screen through the pair of housings 210 and 220 and at least one hinge device.

According to one embodiment of the disclosure, the first area 230a and the second area 230b may have an overall symmetrical shape with respect to the folding area 230c or may have a partially asymmetrical shape.

According to an embodiment of the disclosure, the electronic device 200 may include a first rear cover 240 disposed on a second surface 212 of the first housing 210 and a second rear cover 250 disposed on a fourth surface 222 of the second housing 220. In one embodiment of the disclosure, at least a portion of the first rear cover 240 may be formed integrally with the first lateral member 213. In one embodiment of the disclosure, at least a portion of the second rear cover 250 may be formed integrally with the second lateral member 223.

According to one embodiment of the disclosure, at least one of the first rear cover 240 and the second rear cover 250 may be formed of a substantially transparent plate (e.g., a glass plate including various coating layers, or a polymer plate) or an opaque plate. According to one embodiment of the disclosure, the first rear cover 240 may be formed of an opaque plate, such as, for example, a coated or colored glass, a ceramic, a polymer, a metal (e.g., aluminum, stainless steel (STS), or magnesium), or a combination of at least two of the above materials.

According to one embodiment of the disclosure, the second rear cover 250 may be formed by a substantially transparent plate, such as glass or polymer, for example. Accordingly, the second display 235 may be disposed to be visible from the outside through the second rear cover 250 in the inner space of the second housing 220.

According to one embodiment of the disclosure, the input device 215 may include a plurality of microphones disposed to detect the direction of sound.

According to one embodiment of the disclosure, the audio output devices 227 and 228 may include speakers. According to one embodiment of the disclosure, the audio output devices 227 and 228 may include a call receiver 227 disposed through the fourth surface 222 of the second housing 220 and an external speaker 228 disposed through at least a portion of the second lateral member 223 of the second housing 220.

In one embodiment of the disclosure, the input device 215, the audio output devices 227 and 228 and the connector port 229 may be disposed in spaces of the first housing 210 and/or the second housing 220. The input device 215, the audio output devices 227 and 228 and the connector port 229 may be exposed to the external environment through at least one hole formed in the first housing 210 and/or the second housing 220. In one embodiment of the disclosure, the holes formed in the first housing 210 and/or the second housing 220 may be used in common for the input device 215 and the audio output devices 227 and 228. In one embodiment of the disclosure, the audio output devices 227 and 228 may include a speaker (e.g., a piezo speaker) that operates without the hole formed in the first housing 210 and/or the second housing 220.

According to one embodiment of the disclosure, the camera modules 216a, 216b, and 225 may include a first camera module 216a disposed on a first surface 211 of the first housing 210, a second camera module 216b disposed on a second surface 212 of the first housing 210, and/or a third camera module 225 disposed on a fourth surface 222 of the second housing 220.

According to one embodiment of the disclosure, the electronic device 200 may include a flash 218 disposed near the second camera module 216b. According to one embodiment of the disclosure, the flash 218 may include, for example, a light emitting diode or a xenon lamp.

According to one embodiment of the disclosure, the camera modules 216a, 216b, and 225 may include one or more lenses, image sensors, and/or image signal processors. In one embodiment of the disclosure, at least one of the camera modules 216a, 216b, and 225 may include two or more lenses (e.g., a wide-angle lens and a telephoto lens) and image sensors and may be disposed together on either side of the first housing 210 and/or the second housing 220.

According to one embodiment of the disclosure, the sensor modules 217a, 217b, and 226 may generate electrical signals or data values corresponding to the internal operating state of the electronic device 200 or the external environmental state.

According to one embodiment of the disclosure, the sensor modules 217a, 217b, and 226 may include a first sensor 217a disposed on a first surface 211 of the first housing 210, a second sensor 217b disposed on a second surface 212 of the first housing 210, and/or a third sensor 226 disposed on a fourth surface 222 of the second housing 220. In one embodiment of the disclosure, the sensor modules 217a, 217b, and 226 may include at least one of a gesture sensor, a grip sensor, a color sensor, an infrared (IR) sensor, a light sensor, an ultrasonic sensor, an iris recognition sensor, or a distance detection sensor (e.g., a time of flight (TOF) sensor or a light detection and ranging (LiDAR) sensor).

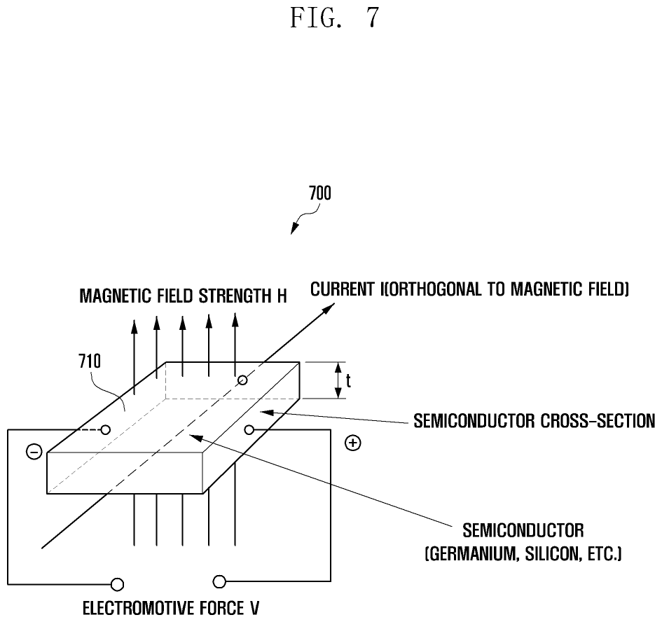

According to one embodiment of the disclosure, the electronic device 200 may further include at least one of a barometric sensor, a magnetic sensor (e.g., a geomagnetic sensor 700 of FIG. 7), a biometric sensor, a temperature sensor, a humidity sensor, or a fingerprint recognition sensor, which are not shown. In one embodiment of the disclosure, the fingerprint recognition sensor may be disposed through at least one of the first lateral member 213 of the first housing 210 and/or the second lateral member 223 of the second housing 220.

According to one embodiment of the disclosure, the key input device 219 may be disposed to be exposed to the outside through the first lateral member 213 of the first housing 210. In one embodiment of the disclosure, the key input device 219 may also be disposed to be exposed to the outside through the second lateral member 223 of the second housing 220. In one embodiment of the disclosure, the electronic device 200 may not include some or all of the key input devices 219, and the key input devices 219 that are not included may be implemented in another form, such as a soft key, on at least one display 230 and 235. In one embodiment of the disclosure, the key input device 219 may be implemented using a pressure sensor included in at least one display 230 and 235.

According to one embodiment of the disclosure, the connector port 229 may include a connector (e.g., a USB connector or an IF module (interface connector port module)) for transmitting and receiving power and/or data with an external electronic device. In one embodiment of the disclosure, the connector port 229 may perform a function for transmitting and receiving audio signals with the external electronic device, or may further include a separate connector port (e.g., an ear jack hole) for performing a function for transmitting and receiving audio signals.

According to one embodiment of the disclosure, at least one of the camera modules 216a, 216b, and 225, at least one of the sensor modules 217a, 217b, and 226, and/or an indicator may be disposed to be visually exposed through at least one display 230 and 235. For example, at least one of the camera modules 216a and 225, at least one of the sensor modules 217a and 226, and/or an indicator may be disposed in an inner space of at least one housing 210 and 220, below an active area (display area) of at least one display 230 and 235. At least one of the camera modules 216a and 225, at least one of the sensor modules 217a and 226, and/or an indicator may be disposed to be in contact with the external environment through an opening perforated to the cover member (the window layer (not shown) and/or the second rear cover 250 of the first display) or a transparent area.

According to one embodiment of the disclosure, an area where at least one display 230 and 235 and at least one camera module 216a and 225 face each other may be formed as a transparent area having a certain transmittance as part of an area displaying content.

According to one embodiment of the disclosure, the transparent area may be formed to have transmittance in the range of about 5% to about 20%. The transmittance area may include an area overlapping with an effective area (e.g., an angle of view area) of at least one camera module 216a and 225 through which light passes to be imaged by the image sensor to generate an image. For example, the transmittance area of the display 230 and 235 may include an area having a lower pixel density than the surrounding area. For example, the transmittance area may replace an opening. For example, the at least one camera module 216a and 225 may include an under display camera (UDC) or an under panel camera (UPC). In one embodiment of the disclosure, some of the camera modules or sensor modules 217a and 226 may be disposed to perform their functions without being visually exposed through the display. For example, an area facing a camera module 216a and 225 and/or a sensor 217a and 226 disposed under a display 230 and 235 (e.g., a display panel) may have an under display camera (UDC) structure, so that a perforated opening may not be necessary.

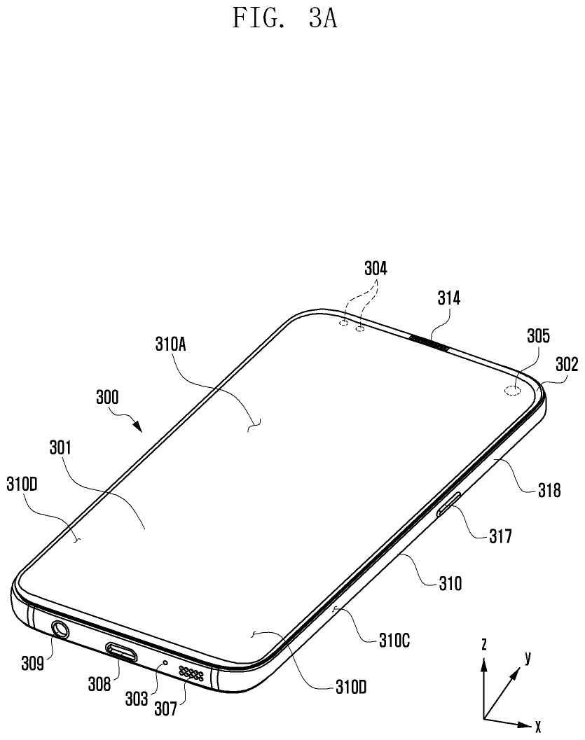

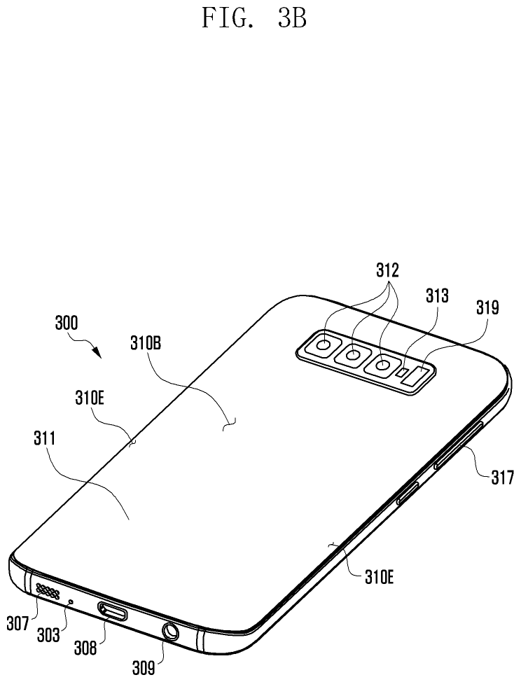

FIG. 3A is a perspective view of a first surface (e.g., a front surface) of an electronic device according to an embodiment of the disclosure.

FIG. 3B is a perspective view of a second surface (e.g., a rear surface) of an electronic device according to an embodiment of the disclosure.

Referring to FIGS. 3A and 3B, an electronic device 300 according to an embodiment of the disclosure (e.g., the electronic device 101 of FIG. 1) may include a first surface (or a front surface) 310A, a second surface (or a rear surface) 310B, and a housing 310. An electronic device 300 (e.g., the electronic device 101 of FIG. 1) according to an embodiment of the disclosure may include a display 301.

According to one embodiment of the disclosure, the display 301 may be supported by a housing 310. For example, the display 301 may include a liquid crystal display (LCD) display, an organic light emitting diodes (OLED) display, or a micro LED display.

According to one embodiment of the disclosure, the housing 310 may include a side surface 310C surrounding a space between the first surface 310A and the second surface 310B. According to one embodiment of the disclosure, the housing 310 may also refer to a structure forming a part of the first surface 310A, the second surface 310B and the side surface 310C.

According to one embodiment of the disclosure, the first surface 310A may be formed by a front plate 302 that is at least partially substantially transparent (e.g., a glass plate including various coating layers, or a polymer plate).

According to one embodiment of the disclosure, the second surface 310B may be formed by a substantially opaque rear plate 311. The rear plate 311 may be formed of, for example, a coated or colored glass, a ceramic, a polymer, a metal (e.g., aluminum, stainless steel (STS), or magnesium), or a combination of at least two of the above materials. However, the disclosure is not limited thereto, and the rear plate 311 may also be formed of transparent glass.

According to one embodiment of the disclosure, the side 310C may be formed by a side bezel structure 318 (or “lateral member”) that is coupled with the front plate 302 and the rear plate 311 and comprises a metal and/or polymer. In one embodiment of the disclosure, the rear plate 311 and the side bezel structure 318 may be formed integrally and comprise the same material (e.g., a metal material, such as aluminum).

According to one embodiment of the disclosure, the front plate 302 may include two first areas 310D that are seamlessly extended from the surface 310A toward the rear plate 311. The two first areas 310D may be disposed at both ends of a long edge of the front plate 302.

According to one embodiment of the disclosure, the rear plate 311 may include two second areas 310E that are seamlessly extended from the surface 310B toward the front plate 302.

According to one embodiment of the disclosure, the front plate 302 (or the rear plate 311) may include only one of the first areas 310D (or the second areas 310E). In one embodiment of the disclosure, some of the first areas 310D or second areas 310E may not be included.

In embodiments of the disclosure, the side bezel structure 318, when viewed from the side surface of the electronic device 300, may have a first thickness (or width) on a side surface that does not include the first area 310D or the second area 310E as described above. In embodiments of the disclosure, the side bezel structure 318, when viewed from the side surface of the electronic device 300, may have a second thickness (or width), that is thinner than the first thickness, on the side surface that includes the first area 310D or the second area 310E.

According to one embodiment of the disclosure, the electronic device 300 may include at least one of a display 301, an audio input device 303 (e.g., the input module 150 of FIG. 1, microphone), an audio output device 307 and 314 (e.g., the audio output module 155 of FIG. 1, speaker) (e.g., an audio module), sensor modules 304 and 319 (e.g., the sensor module 176 of FIG. 1), a camera module 305 and 312 (e.g., the camera module 180 of FIG. 1), a flash 313, a key input device 317, an indicator (not shown), and connectors 308 and 309. According to one embodiment of the disclosure, the electronic device 300 may omit at least one of the components (e.g., the key input device 317) or may additionally include other components.

According to one embodiment of the disclosure, the display 301 may be visually visible through the upper portion of the front plate 302.

According to one embodiment of the disclosure, at least a portion of the display 301 may be visible through the front plate 302 forming the first surface 310A and the first area 310D of the side surface 310C. The display 301 may be coupled to or disposed adjacent to touch sensing circuit, a pressure sensor capable of measuring the intensity (pressure) of a touch, and/or a digitizer capable of detecting a magnetic field type electronic pen (e.g., a stylus pen).

According to one embodiment of the disclosure, at least a portion of the sensor modules 304 and 319, and/or at least a portion of the key input device 317, may be disposed in the first area 310D, and/or the second area 310E.

According to one embodiment of the disclosure, a rear surface of the screen display area of the display 301 may include at least one of a first sensor 304, camera modules 305 and 312 (e.g., image sensors), an audio output device 314 (e.g., audio module), and a fingerprint sensor.

According to one embodiment of the disclosure, the display 301 may be coupled to or disposed adjacent to touch sensing circuit, a pressure sensor capable of measuring the intensity (pressure) of a touch, and/or a digitizer capable of detecting a magnetic field type electronic pen (e.g., a stylus pen).

According to one embodiment of the disclosure, at least a portion of the sensor modules 304 and 319 and/or at least a portion of the key input device 317 may be disposed in the first areas 310D and/or the second areas 310E.

In one embodiment of the disclosure, the audio input device 303 may include a microphone. In one embodiment of the disclosure, the audio input device 303 may include a plurality of microphones disposed to detect the direction of sound.

According to one embodiment of the disclosure, the audio output device 307 and 314 may include an audio output device 307 that operates as an external speaker and an audio output device 314 that operates as a call receiver.

In some embodiments of the disclosure, the audio input device 303 (e.g., microphone), the audio output devices 307 and 314, and the connectors 308 and 309 may be disposed in an inner space of the electronic device 300. The audio input device 303 (e.g., microphone), the audio output devices 307 and 314, and the connectors 308 and 309 may be exposed to the external environment through at least one hole formed in the housing 310. In some embodiments of the disclosure, the holes formed in the housing 310 may be shared for the audio input device 303 (e.g., microphone) and the audio output devices 307 and 314. In some embodiments of the disclosure, the audio output devices 307 and 314 may include speakers (e.g., piezo speakers) that operate without the holes formed in the housing 310.

According to one embodiment of the disclosure, the sensor modules 304 and 319 (e.g., the sensor module 176 of FIG. 1) may generate electrical signals or data values corresponding to an internal operating state of the electronic device 300 or an external environmental state. The sensor modules 304 and 319 may include a first sensor 304 (e.g., a proximity sensor) disposed on a first surface 310A of the housing 310 and/or a second sensor 319 (e.g., a heart rate monitor (HRM) sensor) disposed on a second surface 310B of the housing 310 and/or a third sensor (not shown) (e.g., a fingerprint sensor). For example, the fingerprint sensor may be disposed in the first surface 310A (e.g., the display 301) and/or the second surface 310B of the housing 310.

The electronic device 300 may further include at least one of a gesture sensor, a gyro sensor, a barometric sensor, a magnetic sensor (e.g., the geomagnetic sensor 700 of FIG. 7), an acceleration sensor, a grip sensor, a color sensor, an infrared (IR) sensor, a biometric sensor, a temperature sensor, a humidity sensor and/or an ambient light sensor, which are not shown.

According to one embodiment of the disclosure, the camera modules 305 and 312 may include a first camera module 305 disposed on a first side 310A of the electronic device 300, and a second camera module 312 disposed on a second side 310B. A flash 313 may be disposed around the periphery of the camera modules 305 and 312. The camera modules 305 and 312 may include one or more lenses, an image sensor, and/or an image signal processor. The flash 313 may include, for example, a light emitting diode or a xenon lamp.

According to one embodiment of the disclosure, the first camera module 305 may be disposed at the bottom of the display panel of the display 301 in an under-display camera (UDC) manner. According to one embodiment of the disclosure, two or more lenses (a wide-angle and a telephoto lens) and image sensors may be disposed on one surface of the electronic device 300. According to one embodiment of the disclosure, a plurality of first camera modules 305 may be disposed on a first surface of the electronic device 300 (e.g., the surface on which a screen is displayed) in an under-display camera (UDC) manner.

According to one embodiment of the disclosure, the key input device 317 may be disposed on the surface 310C of the housing 310. According to one embodiment of the disclosure, the electronic device 300 may not include some or all of the above-mentioned key input devices 317, and the key input devices 317 that are not included may be implemented in other forms, such as soft keys on the display 301. According to one embodiment of the disclosure, the key input devices 317 may be implemented using a pressure sensor included on the display 301.

According to one embodiment of the disclosure, the connectors 308 and 309 may include a first connector hole 308 that accommodates a connector (e.g., a USB connector) for transmitting power and/or data to and from an external electronic device, and/or a second connector hole 309 that accommodates a connector for transmitting audio signals to and from an external electronic device (e.g., an earphone jack). The first connector hole 308 may include a universal serial bus (USB) Type A, USB Type B, or USB Type C port. In the case that the first connector hole 308 supports USB Type C, the electronic device 300 (e.g., the electronic device 101 of FIG. 1, the electronic device 200 of FIG. 2A) may support USB power delivery (PD) charging.

According to one embodiment of the disclosure, some of the first and second camera modules 305 and 312, respectively, and/or the first sensor 304 of the sensor modules 304 and 319 may be disposed to be visually visible through the display 301.

According to one embodiment of the disclosure, in the case that the first camera module 305 is disposed in an under display camera (UDC) manner, the first camera module 305 may not be visually visible to the outside.

According to one embodiment of the disclosure, the first camera module 305 may be disposed to overlap with the display area and may also display the screen in the display area corresponding to the first camera module 305. The first sensor 304 may be disposed to perform its function without being visually exposed through the front plate 302 in the inner space of the electronic device 300.

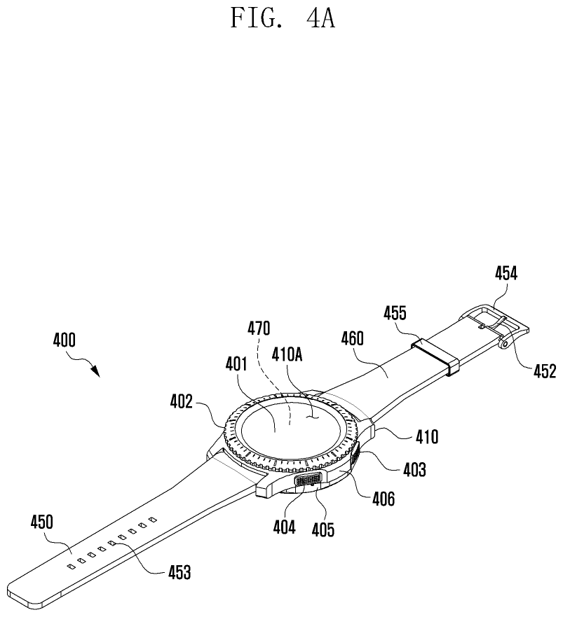

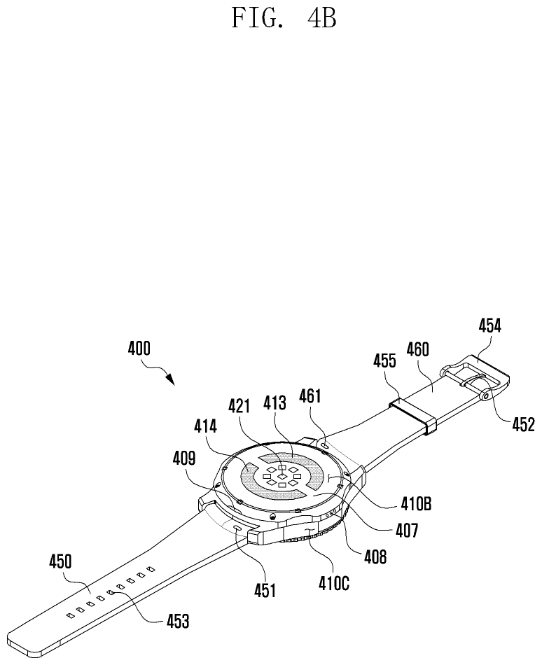

FIG. 4A is a perspective view of a first surface (e.g., a front surface) of an electronic device according to an embodiment of the disclosure.

FIG. 4B is a perspective view of a second surface (e.g., a rear surface) of an electronic device according to an embodiment of the disclosure.

Referring to FIGS. 4A and 4B, an electronic device 400 (e.g., a wearable electronic device) (e.g., the electronic device 101 of FIG. 1, the electronic device 200 of FIG. 2A, the electronic device 300 of FIG. 3A), according to one embodiment of the disclosure, may include a housing 410 and a fastening member 450 and 460.

According to one embodiment of the disclosure, the housing 410 may include a first surface (or a front surface) 410A, a second surface (or a rear surface) 410B, and a side surface 410C surrounding a space between the first surface 410A and the second surface 410B.

According to one embodiment of the disclosure, the fastening member 450 and 460 may be connected to at least a portion of the housing 410 and configured to removably fasten the electronic device 400 to a portion of the user's body (e.g., wrist, ankle).

In another embodiment (not shown) of the disclosure, the housing may refer to a structure forming a portion of the first surface 410A, the second surface 410B, and the side surface 410C of FIG. 4A.

According to one embodiment of the disclosure, the first surface 410A may be formed by a front plate 401 that is at least partially substantially transparent (e.g., a glass plate including various coating layers, or a polymer plate).

In one embodiment of the disclosure, the second surface 410B may be formed by a substantially opaque rear plate 407. The rear plate 407 may be formed by, for example, a coated or colored glass, a ceramic, a polymer, a metal (e.g., aluminum, stainless steel (STS), or magnesium), or a combination of at least two of the above materials.

In one embodiment of the disclosure, the side surface 410C may be formed by a side bezel structure (or “lateral member”) 406 that is coupled with the front plate 401 and the rear plate 407 and comprises a metal and/or a polymer. In some embodiments of the disclosure, the rear plate 407 and the side bezel structure 406 may be formed integrally and comprise the same material (e.g., a metal material, such as aluminum).

According to one embodiment of the disclosure, the fastening member 450 and 460 may be formed of a variety of materials and shapes. The fastening member 450 and 460 may be formed of a fabric, a leather, a rubber, a urethane, a metal, a ceramic, or a combination of at least two of the above materials to allow the integral and plurality of unit links to be mutually fluidly movable.

According to one embodiment of the disclosure, the electronic device 400 may include at least one of a display 470 (e.g., the display module 160 of FIG. 1, the first display 230 of FIG. 2A, the display 301 of FIG. 3A), the audio module 405 and 408 (e.g., the audio module 170 of FIG. 1), the sensor 421 (e.g., the sensor module 176 of FIG. 1), the key input device 402, 403, and 404, and the connector hole 409. In some embodiments of the disclosure, the electronic device 400 may omit at least one of the components (e.g., the key input device 402, 403, and 404, the connector hole 409, or the sensor 421) or may additionally include other components.

According to one embodiment of the disclosure, the display 470 may be exposed through a significant portion of the front plate 401. The shape of the display 470 may correspond to the shape of the front plate 401 and may have various shapes, such as a circle, an oval, or a polygon. The display 470 may be combined with or disposed adjacent to a touch sensing circuit, a pressure sensor capable of measuring the intensity (pressure) of a touch, and/or a fingerprint sensor.

According to one embodiment of the disclosure, the display 470 may display various images under the control of a processor 520. The display 470 may be implemented as one of a liquid crystal display (LCD), a light-emitting diode (LED) display, a micro LED, or an organic light-emitting diode (OLED) display, but is not limited thereto.

According to one embodiment of the disclosure, the display 470 may be formed as a touch screen that detects touch and/or proximity touch (or hovering) input using a part of a user's body (e.g., a finger) or an input device (e.g., a stylus pen). The display 470 may include at least some of the configurations and/or functions of the display module 160 of FIG. 1.

According to one embodiment of the disclosure, the audio module 405 and 408 may include a microphone hole 405 and a speaker hole 408. The microphone hole 405 may have a microphone disposed inside to acquire external sound, and in some embodiments of the disclosure, a plurality of microphones may be disposed to detect the direction of the sound. The speaker hole 408 may be used as an external speaker and a receiver for calls. In some embodiments of the disclosure, the speaker hole 408 and the microphone hole 405 may be implemented as a single hole, or a speaker (e.g., a piezo speaker) may be included without the speaker hole 408.

According to one embodiment of the disclosure, the sensor 421 may generate an electric signal or data value corresponding to an internal operating state of the electronic device 200 or an external environmental state. The sensor 421 may include, for example, a biometric sensor 421 (e.g., HRM sensor) disposed on the second surface 410B of the housing 410.

According to one embodiment of the disclosure, the electronic device 400 may further include at least one of a gesture sensor, a gyro sensor, a barometric pressure sensor, a magnetic sensor (e.g., a geomagnetic sensor 700 of FIG. 7), an acceleration sensor, a grip sensor, a color sensor, an infrared (IR) sensor, a biometric sensor, a temperature sensor, a humidity sensor, or an ambient light sensor, which are not shown.

According to one embodiment of the disclosure, the sensor 421 may include an electrode area 413 and 414 forming a portion of a surface of the electronic device 400 and a bio-signal detection circuit (not shown) electrically connected to the electrode area 413 and 414. For example, the electrode area 413 and 414 may include a first electrode area 413 and a second electrode area 414 disposed on a second surface 410B of the housing 410. The sensor 421 may be configured such that the electrode area 413 and 414 acquires an electric signal from a part of the user's body, and the bio-signal detection circuit detects bio-information of the user based on the electric signal.

According to one embodiment of the disclosure, the electronic device 400 may utilize at least one of an angle sensor, a gyro sensor, a magnetic sensor (e.g., the geomagnetic sensor 700 of FIG. 7), and/or an acceleration sensor to measure the direction and azimuth angle in which the electronic device 400 is moving, and display the measured direction and azimuth angle on the display 470.

According to one embodiment of the disclosure, the key input device 402, 403, and 404 may include a wheel key 402 disposed on a first surface 410A of the housing 410 and rotatable in at least one direction, and/or a side key button 403 and 404 disposed on a side surface 210C of the housing 210. The wheel key 402 may have a shape corresponding to the shape of the front plate 401.

According to one embodiment of the disclosure, the electronic device 400 may not include some or all of the above-mentioned key input devices 402, 403, and 404, and the non-included key input devices 402, 403, and 404 may be implemented in other forms, such as soft keys, on the display 470.

According to one embodiment of the disclosure, the connector hole 409 may include another connector hole (not shown) that may accommodate a connector (e.g., a USB connector) for transmitting and receiving power and/or data with an external electronic device, and may accommodate a connector for transmitting and receiving audio signals with the external electronic device. The electronic device 400 may further include a connector cover (not shown) that covers at least a portion of the connector hole 409 and blocks external foreign substances from entering the connector hole.

According to one embodiment of the disclosure, the fastening member 450 and 460 may be removably fastened to at least a portion of the housing 410 using the locking member 451 and 461. The fastening member 450 and 460 may include one or more of a fixing member 452, a fixing member fastening hole 453, a band guide member 454, and a band fastening ring 455.

According to one embodiment of the disclosure, the fixing member 452 may be configured to fix the housing 410 and the fastening members 450 and 460 to a part of the user's body (e.g., wrist, ankle). The fixing member fastening hole 453 may fix the housing 410 and the fastening members 450 and 460 to a part of the user's body in response to the fixing member 452. The band guide member 454 may be configured to limit the range of movement of the fixing member 452 when the fixing member 452 is fastened to the fixing member fastening hole 453, thereby allowing the fastening members 450 and 460 to be fastened in close contact with a part of the user's body. The band fastening ring 455 may limit the range of movement of the fastening members 450 and 460 when the fixing member 452 and the fixing member fastening hole 453 are fastened.

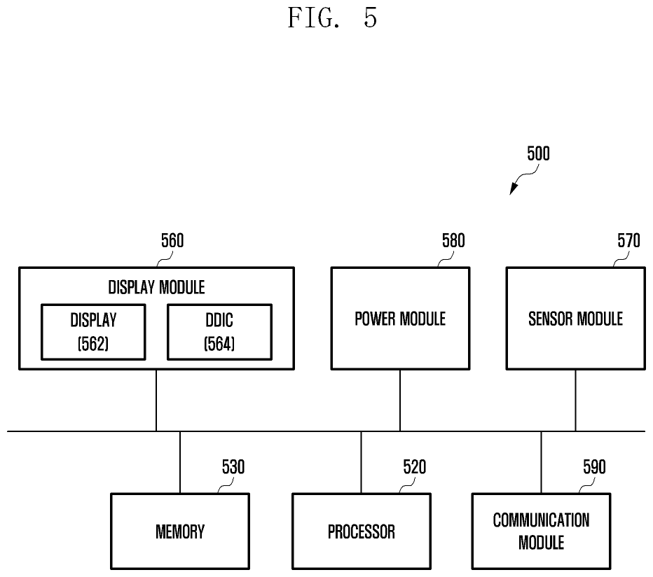

According to one embodiment of the disclosure, the electronic device 400 may include a printed circuit board and a battery (e.g., the battery 189 of FIG. 1, the power module 580 of FIG. 5). The printed circuit board of the electronic device 400 may include a processor (e.g., the processor 120 of FIG. 1, the processor 520 of FIG. 5), memory (e.g., the memory 130 of FIG. 1, the memory 530 of FIG. 5), an interface (e.g., the interface 177 of FIG. 1), and/or a plurality of antennas.

For example, the processor 120 and 520 may include one or more of a central processing unit, an application processor, a graphic processing unit (GPU), an application processor sensor processor, or a communication processor. The electronic device 400 and 500 may include one processor 120 and 520 and may also include a plurality of processors 120 and 520.

For example, the memory 130 and 530 may include volatile memory or non-volatile memory. For example, the interface 177 may include a high definition multimedia interface (HDMI), a universal serial bus (USB) interface, an SD card interface, and/or an audio interface. The interface 177 may electrically or physically connect the electronic device 400 to an external electronic device and may include a USB connector, an SD card/MMC connector, or an audio connector.

For example, a battery (e.g., the battery 189 of FIG. 1, the power module 580 of FIG. 5) may provide power to at least one component of electronic device 400. The battery (e.g., the battery 189 of FIG. 1, the power module 580 of FIG. 5) may include a non-rechargeable primary cell, a rechargeable secondary cell, or a fuel cell. At least a portion of the battery (e.g., the battery 189 of FIG. 1, the power module 580 of FIG. 5) may be disposed substantially on the same plane with the printed circuit board. The battery (e.g., the battery 189 of FIG. 1, the power module 580 of FIG. 5) may be integrally disposed within the electronic device 400, or may be removably disposed with the electronic device 400.

According to one embodiment of the disclosure, the plurality of antennas may include a first antenna and a second antenna. For example, the first antenna may include a near field communication (NFC) antenna, a wireless charging antenna, and/or a magnetic secure transmission (MST) antenna. The first antenna may wirelessly communicate with an external device, wirelessly transmit or receive power for charging, or transmit a magnetic-based signal including a near field communication signal or payment data. For example, the second antenna may include a near field communication (NFC) antenna, a wireless charging antenna, and/or a magnetic secure transmission (MST) antenna. The second antenna may wirelessly communicate with an external device, wirelessly transmit or receive power for charging, or transmit a magnetic-based signal including a near field communication signal or payment data.

FIG. 5 is a block diagram illustrating a configuration of an electronic device according to an embodiment of the disclosure.

Referring to FIG. 5, an electronic device 500 (e.g., the electronic device 400 of FIGS. 4A and 4B, a wearable electronic device) according to one embodiment of the disclosure may include a processor 520 (e.g., the processor 120 of FIG. 1), memory 530 (e.g., the memory 130 of FIG. 1), a display module 560 (e.g., the display module 160 of FIG. 1), at least one sensor 570 (e.g., the sensor module 176 of FIG. 1), a power module 580 (e.g., the power management module 188 and battery 189 of FIG. 1), and a communication module 590 (e.g., the communication module 190 of FIG. 1). The electronic devices 400 and 500 may include at least some of the configuration and/or functionality of the electronic device 101 of FIG. 1, the electronic device 200 of FIG. 2A, and the electronic device 300 of FIG. 3A. At least some of the configurations of each of the electronic devices shown (or not shown) may be operatively, functionally, and/or electrically coupled to each other. The sensor module 570 (e.g., sensor) may include a sensor circuitry.

According to one embodiment of the disclosure, the electronic device 400 and 500 may be a wearable electronic device, such as a smart watch or a smart band.

According to one embodiment of the disclosure, the electronic devices 400 and 500 may be a portable communication device (e.g., the electronic device 200 of FIG. 2A, the electronic device 300 of FIG. 3A), such as a smartphone. For example, the electronic devices 400 and 500 may be a bar type electronic device. For example, the electronic devices 400 and 500 may be a foldable electronic device (or a slidable electronic device).

According to one embodiment of the disclosure, the processor 520 may include one or more processors (e.g., central processing unit (CPU) circuit) configured to perform calculation or data processing related to control and/or communication of the respective components of the electronic devices 400 and 500. The processor 520 may include at least some of the configuration and/or functionality of the processor 120 of FIG. 1.

According to one embodiment of the disclosure, the processor 520 is not limited to the calculation and data processing functions that can be implemented in the electronic devices 400 and 500. For example, the processor 520 may measure geomagnetism using the sensor module 570. For example, the processor 520 may calculate a precision error for determining a new reference azimuth angle using the sensor module 570. For example, the processor 520 may update the new reference azimuth angle. For example, the processor 520 may compare the new precision error with a previous (e.g., existing) precision error to determine whether to compensate for the amount of gyro movement. For example, the processor 520 may calculate an azimuth angle error. For example, the processor 520 may compensate for the azimuth angle error because of magnetic disturbances and display it on a display 562 (e.g., the display 470 of FIG. 4A). For example, the processor 520 may utilize the sensor module 570 to measure biometric information and provide biometric notifications. For example, the operations of the processor 520 may be performed by loading instructions stored in the memory 530.

According to one embodiment of the disclosure, the memory 530 may include main memory and storage (or auxiliary memory). The main memory may include volatile memory, such as dynamic random access memory (DRAM), static RAM (SRAM), or synchronous dynamic RAM (SDRAM). The storage may include at least one of programmable ROM (OTPROM), PROM, EPROM, EEPROM, mask ROM, flash ROM, flash memory, hard drive, or solid state drive (SSD).

According to one embodiment of the disclosure, the memory 530 may include a large-capacity storage device as non-volatile memory. For example, the memory 530 may include at least one of programmable ROM (OTPROM), PROM, EPROM, EEPROM, mask ROM, flash ROM, flash memory, hard drive, or solid state drive (SSD). The memory 530 may store various file data, and the stored file data may be updated according to the operation of the processor 520.

For example, the memory 530 may include instructions for performing operations of the processor 520. Additionally, the memory 530 may include instructions for performing operations of the display module 560, the sensor module 570, and the communication module 590.

According to one embodiment of the disclosure, the sensor module 570 may include a photoplethysmography sensor (PPG sensor), an angle sensor, a gesture sensor, a gyro sensor, a barometric pressure sensor, a magnetic sensor (e.g., the geomagnetic sensor 700 of FIG. 7), an acceleration sensor, a grip sensor, a proximity sensor, a color sensor, an infrared (IR) sensor, a biometric sensor, a temperature sensor, a humidity sensor, or an ambient light sensor.

According to one embodiment of the disclosure, the processor 520 of the electronic devices 400 and 500 may use at least one of an angle sensor, a gyro sensor, a magnetic sensor (e.g., the geomagnetic sensor 700 of FIG. 7), and/or an acceleration sensor to measure the direction and azimuth angle in which the electronic devices 400 and 500 are moving, and display the measured direction and azimuth angle on a display.

According to one embodiment of the disclosure, the processor 520 may measure the direction and azimuth angle in which the electronic devices 400 and 500 are moving using the sensor module 570. The processor 520 may display the measured direction and azimuth angle on a display 562 (e.g., the display 470 of FIG. 4A). The processor 520 may display an error in the azimuth angle on the display 562 (e.g., the display 470 of FIG. 4A). The processor 520 may compensate for the error in the azimuth angle and display it on the display 562 (e.g., the display 470 of FIG. 4A). For example, the processor 520 may display on the display 562 (e.g., the display 470 of FIG. 4A) an error in the previous (e.g., existing) azimuth angle and a new azimuth angle that corrects for the error in the azimuth angle.

According to one embodiment of the disclosure, the processor 520 of the electronic device 400 and 500 may detect the user's biometric information (e.g., heart rate, oxygen saturation (SPO2), stress, and/or blood pressure) using a PPG sensor or a photoplethysmography sensor, and display the biometric information on the display 562.

According to one embodiment of the disclosure, the processor 520 may use the sensor module 570 to detect an operational state of the electronic device 400 and 500 (e.g., power or temperature), or an external environmental state (e.g., user state), and generate an electrical signal or data value corresponding to the detected state. The processor 520 may display information about the operational state of the electronic devices 400 and 500, or the external environmental state on the display 562.

According to one embodiment of the disclosure, the display module 560 may include a display 562 (e.g., the display 470 of FIG. 4A) and a display driver integrated circuit (DDIC) 564 (hereinafter referred to as “DDIC 564”) that drives the display 562.

According to one embodiment of the disclosure, the processor 520 may control the operation of the DDIC 564. The display 562 may display various images based on the control of the DDIC 564. The display 562 may be implemented as one of, but not limited to, a liquid crystal display (LCD), a light-emitting diode (LED) display, a micro-LED, or an organic light-emitting diode (OLED) display.

According to one embodiment of the disclosure, the display module 560 may include a sensor panel (e.g., digitizer, touch screen) that detects touch and/or proximity touch (or hovering) input using a part of a user's body (e.g., a finger) or an input device (e.g., a stylus pen). The display module 560 may include at least some of the configurations and/or functions of the display module 160 of FIG. 1.

According to one embodiment of the disclosure, the power module 580 may include a power management module (e.g., the power management module 188 of FIG. 1) and a battery (e.g., the battery 189 of FIG. 1) for providing driving power for the electronic devices 400 and 500. For example, the power management module 188 may manage the power supplied to the electronic devices 400 and 500 and may charge the battery 189. The power management module 188 may be implemented as at least a portion of a power management integrated circuit (PMIC). For example, the battery 189 may provide power to at least one component of the electronic devices 400 and 500. The battery 189 may include a non-rechargeable primary cell, a rechargeable secondary cell, or a fuel cell.

According to one embodiment of the disclosure, the communication module 590 may communicate with an external device through a wireless network under the control of the processor 520. The communication module 590 may include hardware and software modules for transmitting and receiving data from a cellular network (e.g., a long term evolution (LTE) network, a 5G network, a new radio (NR) network) and a short-range network (e.g., Wi-Fi, Bluetooth, Bluetooth low energy). The communication module 590 may include at least some of the configurations and/or functions of the communication module 190 of FIG. 1.

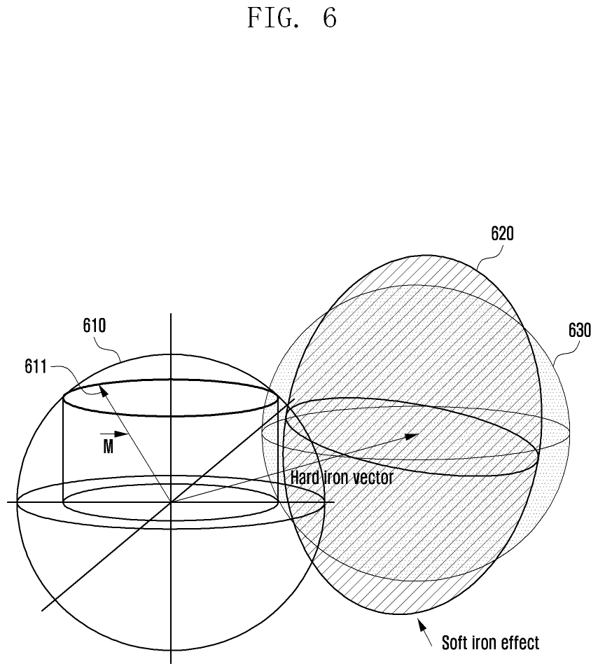

FIG. 6 is a diagram illustrating components of ambient magnetic force for providing azimuth angle information in an electronic device according to an embodiment of the disclosure.

FIG. 7 is a diagram illustrating a method performed by a geomagnetic sensor according to an embodiment of the disclosure.

Referring to FIGS. 6 and 7, a sensor (e.g., the sensor module 570 of FIG. 5) of an electronic device (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5) may include a geomagnetic sensor (e.g., the geomagnetic sensor 700 of FIG. 7) (e.g., a three-axis geomagnetic sensor).

According to one embodiment of the disclosure, a sensor (e.g., the sensor module 570 of FIG. 5) may include sensor circuit of at least one of a Hall effect sensor, an anisotropic magnetoresistance (AMR) sensor, a giant magnetoresistance (GMR) sensor, and/or a tunneling magnetoresistance (TMR) sensor capable of converting an external magnetic force into an analog signal. For example, a Hall effect sensor, an anisotropic magnetoresistance (AMR) sensor, a giant magnetoresistance (GMR) sensor, and/or a tunneling magnetoresistance (TMR) sensor may include an analog digital converter (ADC) that can convert an analog signal to a digital signal.

For example, a Hall effect sensor, an anisotropic magnetoresistive (AMR) sensor, a giant magnetoresistive (GMR) sensor, and/or a tunneling magnetoresistive (TMR) sensor may include a register internally. A Hall effect sensor, an anisotropic magnetoresistive (AMR) sensor, a giant magnetoresistive (GMR) sensor, and/or a tunneling magnetoresistive (TMR) sensor may use the register value to configure a measurement sensitivity and a measurement time.

For example, the geomagnetic sensor 700 may include a Hall effect sensor. The geomagnetic sensor 700 may measure the magnetic force (or geomagnetic force) inside the electronic device 101, 200, 300, 400, and 500 and the magnetic force (or geomagnetic force) outside the electronic device 101, 200, 300, 400, and 500. The geomagnetic sensor 700 may include an ADC converter that can convert an analog signal to a digital signal. The geomagnetic sensor 700 may convert analog signals for the x-axis, y-axis, and z-axis into 3D digital signal values. The geomagnetic sensor 700 may include internal registers, and the register values may be used to configure the measurement sensitivity and measurement time. The geomagnetic sensor 700 may measure the magnetic force (or geomagnetic force) in the x-axis, y-axis, and z-axis and represent it as a digital value. The geomagnetic sensor 700 may change the time resolution at which it can measure (or recognize) magnetic force changes based on register configurations. For example, a processor (e.g., the processor 120 of FIG. 1, the processor 520 of FIG. 5) may change the register configuration values of the geomagnetic sensor 700 in real time. For example, the processor (e.g., the processor 120 of FIG. 1, the processor 520 of FIG. 5) may change the register configuration values of the geomagnetic sensor 700 in predetermined time increments. For example, the processor (e.g., the processor 120 of FIG. 1, the processor 520 of FIG. 5) may change the register configuration value of the geomagnetic sensor 700 when a predetermined condition is met.

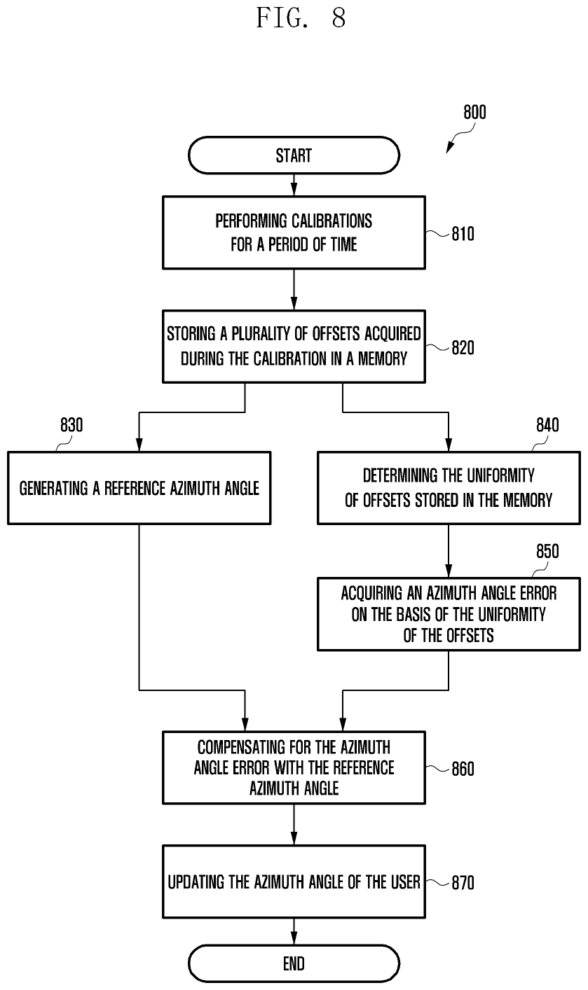

According to one embodiment of the disclosure, the electronic device 101, 200, 300, 400, and 500 may provide a compass function. To provide the compass function, when the user moves the electronic device 101, 200, 300, 400, and 500 in a FIG. 8 shape (or rotates 360 degrees), the geomagnetic sensor 700 may acquire magnetic data for three axes (e.g., x-axis, y-axis, and z-axis). For example, the magnetometer sensor 700 may generate about 100 three-axis (e.g., x-axis, y-axis, and z-axis) magnetism data per second. The processor 520 may acquire about 100 three axis (e.g., x-axis, y-axis, and z-axis) magnetic data per second.

The processor 520 of the electronic device 101, 200, 300, 400, and 500 may generate a virtual sphere 610 based on the three-axis (e.g., x-axis, y-axis, and z-axis) magnetic data. The processor 520 of the electronic device 101, 200, 300, 400, and 500 may acquire the magnetic data of a distorted sphere 620 (soft iron) by removing the center point (e.g., hard iron) component of the virtual sphere 610. For example, hard iron and soft iron may be caused by a variety of sources. Hard iron may be caused by objects that generate their own magnetic field (e.g., magnets, wires, charged objects). Soft iron is a distortion of the magnetic field lines that does not change the origin of the magnetic data, and only the shape of the sphere may change.

According to one embodiment of the disclosure, “M” illustrated in FIG. 6 may refer to a magnitude of the Earth's magnetic field (e.g., about 40 uT). The arrival points of the arrows 611 may represent digital outputs in the x-axis, y-axis, and z-axis of values from the calibrated geomagnetic sensor.

For example, the hard iron may be compensated by correcting the coordinates as much as the strength of the ambient magnetic field of the electronic device 101, 200, 300, 400, and 500 changes. The hard iron may be compensated by offsetting the center point of the virtual sphere 610 to the origin (0, 0 location).

For example, when a conductive metal is disposed in the vicinity of an electronic device 101, 200, 300, 400, and 500, the Earth's magnetic field may be distorted to produce the distorted sphere 620 (soft iron). The electronic device 101, 200, 300, 400, and 500 may compensate for the center point (e.g., hard iron) and the distorted sphere 620 (soft iron) of the virtual sphere 610 having a skewed origin to generate a compensated sphere 630.

For example, the electronic device 101, 200, 300, 400, and 500 may provide a compass function by acquiring azimuth angle information from the compensated magnetic data. For example, the compass function of the electronic device 101, 200, 300, 400, and 500 may be displayed visually in the display (e.g., the display 470 of FIG. 4A, the display 562 of FIG. 5) through the user interface (UI).

According to one embodiment of the disclosure, a magnetic disturbance may occur in a variety of environments that can affect magnetic data when the geomagnetic sensor of the electronic device 101, 200, 300, 400, and 500 (e.g., smartphone, wearable electronic device, smartwatch) measures magnetism.

For example, a magnetic disturbance may occur in an environment where objects (e.g., magnets, wires, charged objects) that generate their own magnetic fields are located in the vicinity of the electronic device 101, 200, 300, 400, and 500 (e.g., smartphone, wearable electronic, smartwatch).

For example, the magnetic disturbance data may become unstable when the electronic device 101, 200, 300, 400, and 500 (e.g., smartphone, wearable electronic device, smartwatch) is moved from indoors to outdoors.

For example, the magnetic disturbance data may become unstable when the electronic device 101, 200, 300, 400, and 500 (e.g., smartphone, wearable electronic device, smart watch) is moved from outdoors to indoors.

For example, the magnetic disturbance data may become unstable when the electronic device 101, 200, 300, 400, and 500 (e.g., smartphone, wearable electronic device, smartwatch) is moved from outside of a vehicle to inside the vehicle.

For example, the magnetic disturbance data may become unstable when the electronic device 101, 200, 300, 400, and 500 (e.g., smartphone, wearable electronic device, smartwatch) is moved from inside the vehicle to outside the vehicle.

For example, the magnetic disturbance data may become unstable when the vehicle in which the electronic device 101, 200, 300, 400, and 500 (e.g., smartphone, wearable electronic device, smartwatch) is located moves from outdoors to indoors.

For example, the magnetic disturbance data may become unstable when the vehicle in which the electronic device 101, 200, 300, 400, and 500 (e.g., smartphone, wearable electronic device, smartwatch) is located is moved from indoors to outdoors.

Referring to FIG. 7, when electrons flowing through the semiconductor 710 (or conductor) of the geomagnetic sensor 700 are subjected to an external magnetic field, a potential difference is formed. For example, germanium or silicon may be used as the material for the semiconductor 710, and the potential difference formed in the semiconductor 710 may represent an electromotive force (voltage). The geomagnetic sensor 700 may detect the external magnetic field by matching the strength of the external magnetic field to the strength of the corresponding electromotive force.

FIG. 8 is a flowchart 800 illustrating a method performed by an electronic device according to an embodiment of the disclosure.

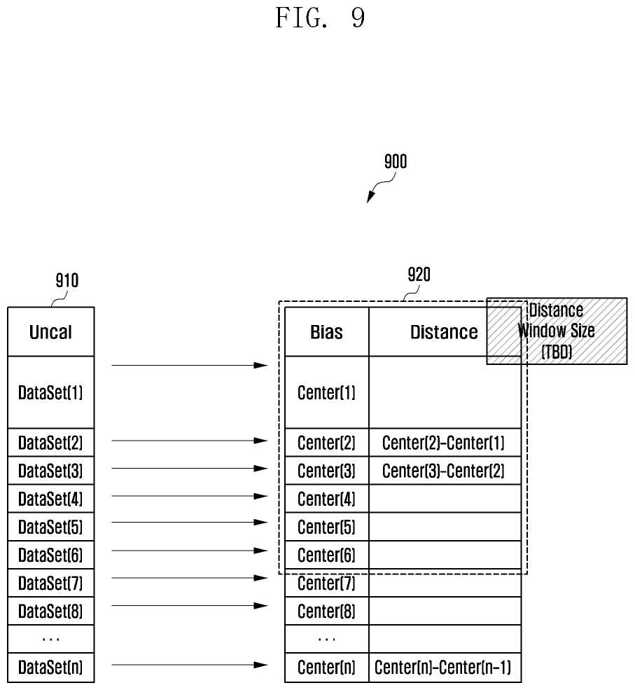

FIG. 9 is a diagram 900 illustrating an offset value acquired from a geomagnetic data set according to an embodiment of the disclosure.

In the following embodiments of the disclosure, each operation may be performed sequentially, but is not necessarily performed sequentially. For example, the order of the operations may be changed, and at least two operations may be performed in parallel.

Referring to FIG. 9, it may be understood that operations 810 to 870 are performed in the processor (e.g., the processor 120 of FIG. 1, the processor 520 of FIG. 5) of the electronic device 500 (e.g., e.g., the electronic device 200 of FIG. 2A, the electronic device 300 of FIG. 3A, the electronic device 400 of FIGS. 4A and 4B).

Referring to FIGS. 5, 8, and 9, in operation 810, a calibration of an azimuth angle may be performed to perform a compass function of the electronic device 500 (e.g., the electronic device 101 of FIG. 1, the electronic device 200 of FIG. 2A, the electronic device 300 of FIG. 3A, the electronic device 400 of FIGS. 4A and 4B). For example, a user may perform the calibration by moving the electronic device 101, 200, 300, 400, and 500 in a figure of 8 (or a 360-degree rotation). For example, the calibration may be performed for a period of time (from about 5 seconds to about 10 seconds).

In operation 820, the geomagnetic sensor (e.g., the geomagnetic sensor 700 of FIG. 7) may acquire magnetic data 910 for the three axes (e.g., the x-axis, y-axis, and z-axis) during the calibration operation. The geomagnetic sensor 700 may provide the acquired offsets (e.g., magnetic data) to a processor 520 (e.g., the processor 120 of FIG. 1). The processor 520 may store the plurality of offsets (e.g., offset1, offset2, - - - , offsetN) (e.g., magnetic data) acquired during the calibration in memory 530 (e.g., the memory 130 of FIG. 1).

For example, performing the azimuth angle calibration may generate a plurality of offsets (e.g., offset1, offset2, - - - , offsetN) that estimate a magnetic offset inside the housing of the electronic device 101, 200, 300, 400, and 500 excluding the Earth's magnetic field. The processor 520 may update the plurality of offsets (e.g., offset1, offset2, - - - , offsetN).

For example, the memory 530 may include a plurality of buffers (e.g., N buffers). The processor 520 may store N offsets (e.g., offset1, offset2, . . . , offsetN) in a plurality of buffers (e.g., N buffers).

In operation 830, the processor 520 may acquire median values 920 (e.g., center value) of N offsets (e.g., offset1, offset2, . . . , offsetN). The processor 520 may calculate (e.g., generate) a new reference azimuth angle based on the middle values 920 (e.g., center value) among N offsets (e.g., offset1, offset2, . . . , offsetN).

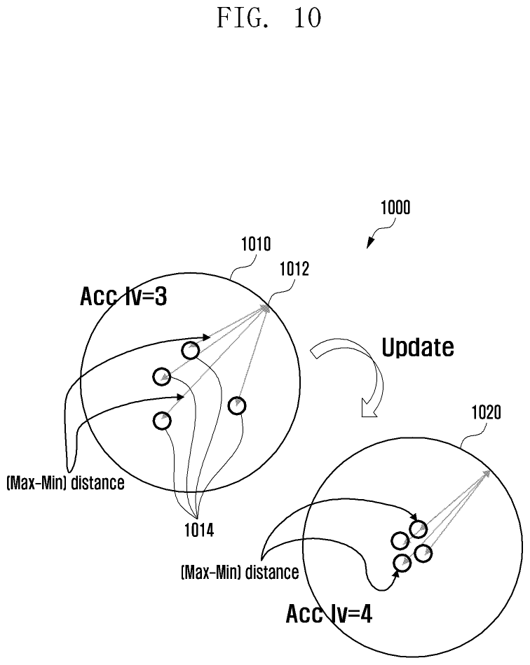

FIG. 10 is a diagram 1000 illustrating updating an accuracy level of azimuth angle according to an embodiment of the disclosure.

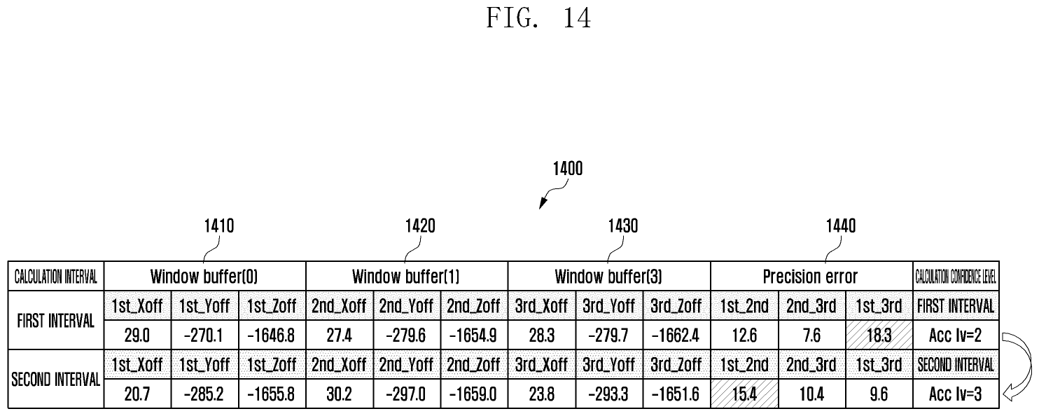

Referring to FIG. 10, the processor 520 may calculate a distance (e.g., 1+2+ . . . +(N−2)+(N−1) distances) between the plurality of points 1014 that may be combined from the N offsets stored in the buffers and a reference point 1012. The processor 520 may acquire the largest value (max) and the smallest value (min) of the distance (e.g., 1+2+ . . . +(N−2)+(N−1) distances) between the plurality of points 1014 and the reference point 1012. The processor 520 may configure (or specify) the largest value (max) of the plurality of point distances (e.g., 1+2+ . . . +(N−2)+(N−1) distances) as the precision error. The processor 540 may store the largest value (max) of the plurality of point distances (e.g., 1+2+ . . . +(N−2)+(N−1) distances) as the precision error value (precision error value 1440 of FIG. 14) in the memory 530.

The distance between the reference point 1012 and the plurality of points 1014 (e.g., 1+2+ . . . +(N−2)+(N−1) distances) may represent a distance between three-dimensional (3D) coordinates. The processor 520 may calculate the distances of the points (e.g., 1+2+ . . . +(N−2)+(N−1) distances) using Equation 1 below.

Distance between points (distance)=offset1 (x1, y1, z1), offset2(x2, y2, z2) to sqrt {(x1−x2)\hat{ }2+(y1−y2)\hat{ }2+(z1−z2)\hat{ }2} Equation 1

The above Equation 1 is merely an example to help understanding and is not limited thereto, and may be modified, applied, or expanded in various ways.

In Equation 1, x may mean the x-axis data, y may mean the y-axis data, and z may mean z-axis data.

When calculating (e.g., generating) a new reference azimuth angle, errors in magnetic disturbance environments may be reduced in the case that the median value 920 (e.g., center value) of the N offsets (e.g., offset1, offset2, - - - , offsetN) are used.

In operation 840, the processor 520 may determine the density (e.g., uniformity) of offsets stored in the memory 530.

The processor 520 may perform operation 830 and operation 840 simultaneously, sequentially, or in parallel.

In operation 850, the processor 520 may acquire an azimuth angle error based on the uniformity of the offsets. The processor 520 may store the azimuth angle error based on the uniformity of the offsets in the memory 530.

In operation 860, the processor 520 may compensate for the azimuth angle by reflecting the azimuth angle error (acquired in operation 850) to the reference azimuth angle (generated in operation 830). The processor 520 may store the compensated azimuth angle in the memory 530.

In operation 870, the processor 520 may update the compensated azimuth angle as a new azimuth angle.

For example, a certain number of azimuth angle errors based on the uniformity of the offsets may be categorized and configured as an accuracy level of the azimuth angle (e.g., level 0 to level 5). The processor 520 may categorize an accuracy level 1010 of the previous (e.g., existing) azimuth angle as level 3 (Acc lv=3) based on the uniformity of the offsets. The processor 520 may classify an accuracy level 1020 of the compensated azimuth angle as level 4 (Acc lv=4) based on the uniformity of the offsets, and may update the accuracy level of the azimuth angle.

For example, the processor 520 may measure an azimuth angle using a geomagnetic sensor (e.g., the geomagnetic sensor 700 of FIG. 7) and display the measured direction and azimuth angle on a display (e.g., the display 470 of FIG. 4A, the display 562 of FIG. 5). For example, an azimuth angle error because of a magnetic disturbance may be displayed in the display (e.g., the display 470 of FIG. 4A, the display 562 of FIG. 5). For example, the processor 520 may compensate for the azimuth angle error because of the magnetic disturbance and display the compensated azimuth angle on the display (e.g., the display 470 of FIG. 4A, the display 562 of FIG. 5). For example, the processor 520 may display the azimuth angle error because of the magnetic disturbance and the corrected azimuth angle together on the display (e.g., the display 470 of FIG. 4A, the display 562 of FIG. 5).

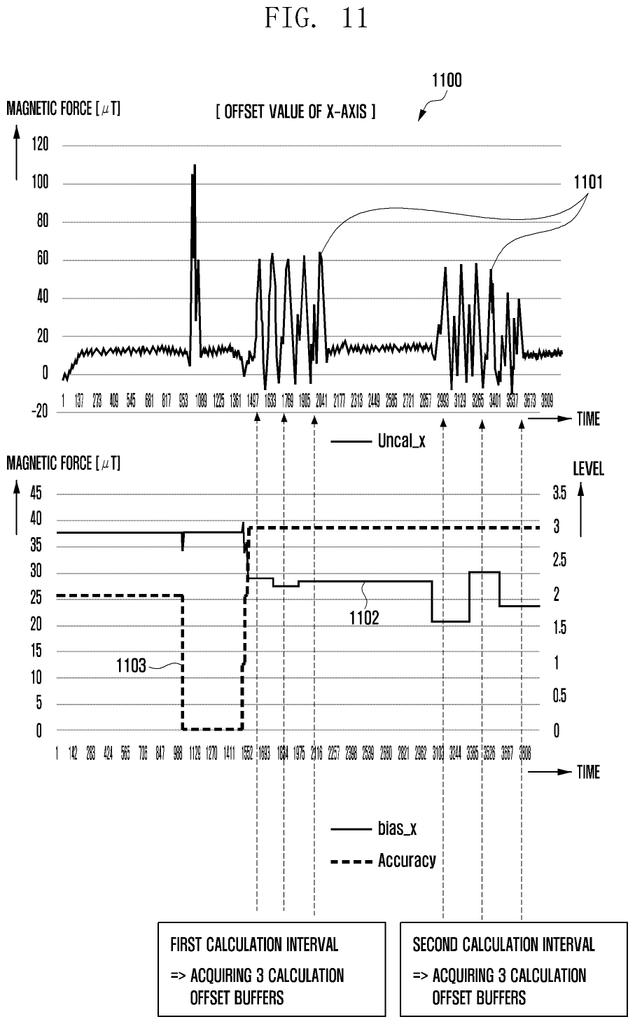

FIG. 11 is a diagram 1100 illustrating offset values of an x-axis stored in a buffer (e.g., memory) by performing a calibration of the geomagnetic sensor according to an embodiment of the disclosure.

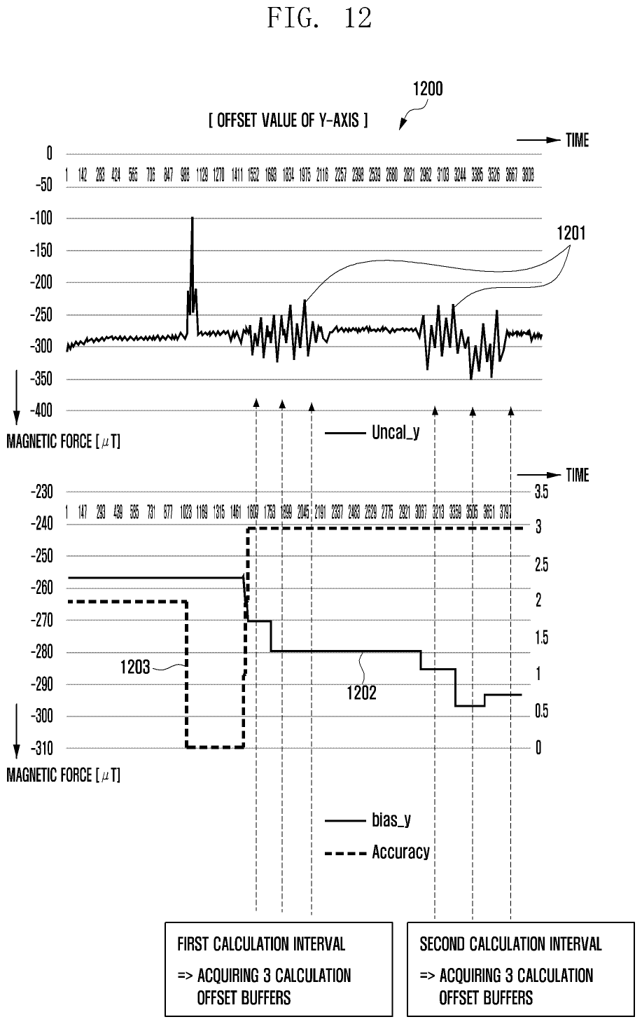

FIG. 12 is a diagram 1200 illustrating offset values of a y-axis stored in a buffer (e.g., memory) by performing a calibration of the geomagnetic sensor according to an embodiment of the disclosure.

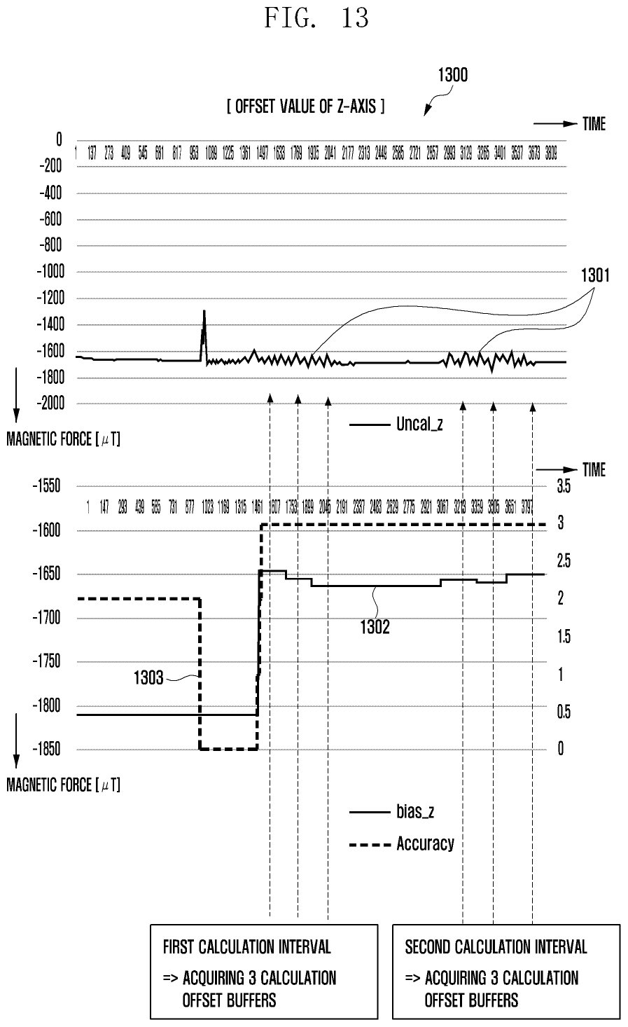

FIG. 13 is a diagram illustrating offset values of a z-axis stored in a buffer (e.g., memory) by performing a calibration of a geomagnetic sensor according to an embodiment of the disclosure.

Referring to FIGS. 11, 12, and 13, horizontal axis (e.g., x-axis) may mean time (e.g., μsec) and vertical axis (e.g., y-axis) may mean magnetic force (e.g., micro-tesla (μT)).

FIG. 14 is a diagram 1400 illustrating calculating precision error based on offset values of geomagnetic data according to an embodiment of the disclosure.

Referring to FIGS. 11, 12, 13, and 14, for calibration of an electronic device (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5), when the electronic devices 101, 200, 300, 400, and 500 are moved in a figure of 8 (or a rotation of about 360 degrees), the geomagnetic sensor 700 may acquire magnetic data about three axes (e.g., the x-axis, y-axis, and z-axis).

According to one embodiment of the disclosure, primary and secondary calibrations of electronic devices 101, 200, 300, 400, and 500 may be performed.

For example, in the first calibration interval, the electronic device 101, 200, 300, 400, and 500 (e.g., the terminal) may be moved, and the adjustment value may be updated a number of times corresponding to a certain buffer size when the movement of the electronic device 101, 200, 300, 400, and 500 satisfies a calibration condition (e.g., a figure of 8 movement or a rotation of about 360 degrees).

For example, in the second calibration interval, the electronic devices 101, 200, 300, 400, and 500 may be further moved and the new calibration values may be updated a number of times corresponding to a certain buffer size. In this case, the second calibration may be performed whenever the electronic devices 101, 200, 300, 400, and 500 are moved, regardless of whether the movement of the electronic devices 101, 200, 300, 400, and 500 is user-intended or user-unintended.

According to one embodiment of the disclosure, a geomagnetic sensor (e.g., the sensor module 570 of FIG. 5, the geomagnetic sensor 700 of FIG. 7) may generate about 100 three-axis (e.g., x-axis, y-axis, and z-axis) magnetic data per second. The processor 520 may acquire about 100 three-axis (e.g., x-axis, y-axis, and z-axis) magnetic data per second from the geomagnetic sensors 570 and 700.

For example, the “1101” illustrated in FIG. 11 represents magnetic data (e.g., raw data) for magnetic force in the x-axis among magnetic data (e.g., raw data) output by sensing magnetic force through the geomagnetic sensors 570 and 700. The “1201” illustrated in FIG. 12 represents magnetic data (e.g., raw data) for magnetic force in the y-axis among magnetic data (e.g., raw data) output by sensing magnetic force through the geomagnetic sensors 570 and 700. The “1301” illustrated in FIG. 13 represents magnetic data (e.g., raw data) for magnetic force in the z-axis among magnetic data (e.g., raw data) output by sensing magnetic force through the geomagnetic sensors 570 and 700.

For example, the “1102” (e.g., a staircase graph) illustrated in FIG. 11 represents a calibration value 1102 for the magnetic force in the x-axis to which the raw data of the magnetic force in the x-axis has been corrected, and a trend of change in the calibration value may be observed through the calibration value 1102 for the magnetic force in the x-axis acquired at a plurality of time points (e.g., three time points). The ‘1202’ (e.g., a staircase graph) illustrated in FIG. 12 represents a calibration value 1202 for the magnetic force of the y-axis to which the raw data of the magnetic force of the y-axis has been corrected, and a trend of change in the calibration value may be observed through the calibration value 1202 for the magnetic force in the y-axis acquired at a plurality of time points (e.g., three time points). The “1302” illustrated in FIG. 13 (e.g., a staircase graph) represents a calibration value 1302 for the magnetic force of the z-axis to which the raw data of the magnetic force of the z-axis has been corrected, and a trend of change in the calibration value may be observed through the calibration value 1302 for the magnetic force of the z-axis acquired at a plurality of time points (e.g., three time points).

For example, the “1103” (e.g., a dotted line graph) illustrated in FIG. 11 may mean an accuracy level 1103 for the calibration values 1102 of the x-axis, which may be represented by a plurality of accuracy levels (e.g., level 0 to level 3, or level 0 to level 4). The processor (e.g., the processor 120 of FIG. 1, the processor 520 of FIG. 5) may update the accuracy level 1103 (e.g., the previous (e.g., existing) azimuth angle level 1010 of FIG. 10) (e.g., the compensated azimuth angle level 1020 of FIG. 10) of the azimuth angle of the x-axis based on the uniformity of the offsets.

For example, the “1203” (e.g., a dotted line graph) illustrated in FIG. 12 may mean an accuracy level 1203 for the calibration values 1202 of the y-axis, which may be represented by a plurality of accuracy levels (e.g., level 0 to level 3, or level 0to level 4). The processor 120 and 520 may update the accuracy level 1203 (e.g., the previous (e.g., existing) azimuth angle accuracy level 1010 of FIG. 10) (e.g., the compensated azimuth angle accuracy level 1020 of FIG. 10) of the y-axis azimuth angle based on the uniformity of the offsets.

For example, the “1303” (e.g., a dotted line graph) illustrated in FIG. 13 may mean an accuracy level 1303 for the calibration values 1302 of the z-axis, which may be represented by a plurality of accuracy levels (e.g., level 0 to level 3, or level 0 to level 4). The processor 120 and 520 may update the accuracy level 1303 (e.g., the previous (e.g., existing) azimuth angle accuracy level 1010 of FIG. 10) (e.g., the compensated azimuth angle accuracy level 1020 of FIG. 10) of the z-axis azimuth angle based on the uniformity of the offsets.

The processor 120 and 520 may acquire a plurality of offsets from the magnetic data 1101, 1201, and 1301 in the three axes (e.g., x-axis, y-axis, and z-axis). The processor 120 and 520 may store the plurality of offsets (e.g., offset1, offset2, - - - , offsetN) in a plurality of buffers. For example, the processor 120 and 520 may acquire three offsets for each of the x-axis, y-axis, and z-axis, and store the three offsets for each of the x-axis, y-axis, and z-axis in the plurality of buffers.

According to one embodiment of the disclosure, the processor 520 may acquire three offsets for the x-axis in the first calibration interval. The processor 520 may store the values of the three acquired offsets for the x-axis in a first buffer 1410 (e.g., window buffer 0) of memory (e.g., the memory 530 of FIG. 5).

Referring to FIGS. 11 and 14, according to one embodiment of the disclosure, the processor 520 may acquire three offsets for the x-axis during the second calibration interval. The processor 520 may store the values of the three offsets in a first buffer 1410 (e.g., window buffer 0) of memory (e.g., the memory 530 of FIG. 5). The processor 520 may acquire the values of the three offsets for the x-axis stored in the first buffer 1410 (e.g., window buffer 0) and calculate a precision error for the x-axis. Referring to FIGS. 12 and 14, according to one embodiment of the disclosure, the processor 520 may acquire the three offsets for the y-axis during the first calibration interval. The processor 520 may store the values of the three acquired offsets for the y-axis in a second buffer 1420 (e.g., window buffer 1) of memory (e.g., the memory 530 of FIG. 5). In the second calibration interval, the processor 520 may acquire the three offsets for the y-axis and store the values of the three offsets in the second buffer 1420 (e.g., window buffer 1) of memory (e.g., the memory 530 of FIG. 5). The processor 520 may acquire the values of the three offsets for the y-axis stored in the second buffer 1420 (e.g., window buffer 1), calculate a precision error, and store the precision error value 1440 in the memory 530.

Referring to FIGS. 13 and 14, according to one embodiment of the disclosure, the processor 520 may acquire three offsets for the z-axis in the first calibration interval. The processor 520 may store the values of the three acquired offsets for the z-axis in a third buffer 1430 (e.g., window buffer 2) of a memory (e.g., the memory 530 of FIG. 5). In the second calibration interval, the processor 520 may acquire the three offsets for the z-axis and store the values of the three offsets in the third buffer 1430 (e.g., window buffer 2) of memory (e.g., the memory 530 of FIG. 5). The processor 520 may acquire the values of the three offsets for the z-axis stored in the third buffer 1430 (e.g., window buffer 2), calculate a precision error, and store the precision error value 1440 in the memory 530. According to one embodiment of the disclosure, the processor 520 may compare the acquired precision error values 1440 for the first calibration interval and the second calibration interval. Based on the results of the comparison of the acquired precision error values 1440, the processor 520 may update the accuracy level of the azimuth angle (e.g., update from level 2 to level 3).

According to one embodiment of the disclosure, the processor 120 and 520 may update the accuracy level of the azimuth angle through the first calibration and the second calibration, wherein the accuracy level may be updated in a plurality of steps (e.g., a total of three steps).

For example, 1st_Xoff may mean the first step of the bias for the x-axis of the sensor x-axis, y-axis, and z-axis in the graph. 2nd_Xoff may mean the second step, and 3nd_Xoff may mean the third step.

For example, the processor 120 and 520 may generate a first accuracy in a first calibration interval. The processor 120 and 520 may acquire three calibration values for the x-axis, y-axis, and z-axis. The largest of the distance values between two points calculated for the number of all possible cases (1-2/2-3/3-1 and operations) based on the three acquired calibration values may be defined as the precision error. The processor 120 and 520 may match the confidence level of the calibration according to the corresponding precision error.

For example, the processor 120 and 520 may generate a second accuracy in the second calibration interval. The accuracy level 1103 of the x-axis illustrated in FIG. 11 may mean the accuracy with which one calibration value 1102 is acquired. The accuracy level 1103 in the x-axis illustrated in FIG. 11 may mean the degree of accuracy with which the calibration value 1102 is acquired from the magnetic data 1101 (e.g., raw data) for the magnetic force in the x-axis acquired from the geomagnetic sensor 570 and 700. The accuracy level 1203 in the y-axis illustrated in FIG. 12 may mean the accuracy with which one calibration value 1202 is acquired. The accuracy level 1203 of the y-axis illustrated in FIG. 12 may mean the degree of accuracy with which the calibration value 1202 is acquired from the magnetic data 1201 (e.g., raw data) for the magnetic force in the y-axis acquired from the geomagnetic sensor 570 and 700. The accuracy level 1303 in the z-axis illustrated in FIG. 13 may mean the accuracy with which one calibration value 1302 is acquired. The accuracy level 1303 of the z-axis may mean the degree of accuracy with which the calibration value 1302 is acquired from the magnetic data 1301 (e.g., raw data) for the magnetic force in the z-axis acquired from the geomagnetic sensor 570 and 700. The processor 120 and 520 may determine a degree of uniformity between the secondary calibration values acquired during the second calibration interval, which may indicate an accuracy level indicative of how confidently the calibration values have been acquired. The processor 120 and 520 may compare a first precision error acquired in the first calibration to a second precision error acquired in the second calibration. The processor 120 and 520 may determine that the calibration value is acquired in the more reliable environment in the case that the secondary precision is lower than the primary precision and may update the calibration value.

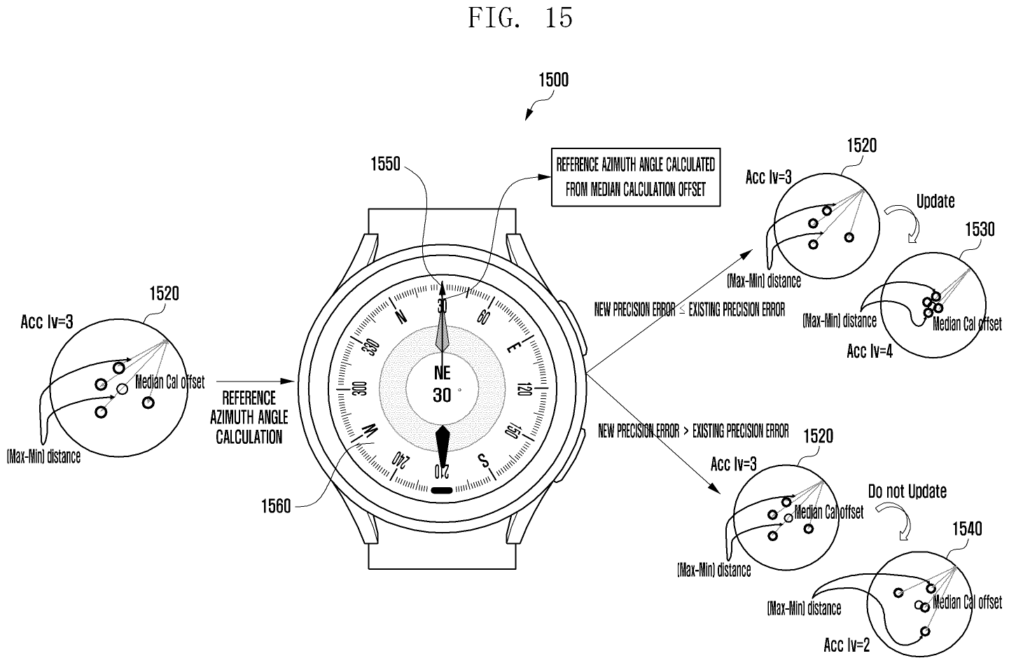

FIG. 15 is a diagram illustrating updating an accuracy level by comparing a relationship between an offset value stored in a buffer and a median value and a precision error according to an embodiment of the disclosure.

Referring to FIG. 15, a reference azimuth angle 1550 may be displayed on a display 1560 (e.g., the display 562 of FIG. 5) of an electronic device 1500 (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5).

According to one embodiment of the disclosure, when a new calibration is performed, the processor (e.g., the processor 120 of FIG. 1, the processor 520 of FIG. 5) may update the new offsets by a size of a buffer in memory (e.g., the memory 130 of FIG. 1, the memory 530 of FIG. 5). After calculating the new precision error, the processor 520 may compare the new precision error (e.g., the new precision error value) with a previous (e.g., existing) precision error (e.g., the existing precision error value).

In the case that, as a result of the comparison of the precision errors, the new precision error (e.g., the new precision error value) is greater than the previous (e.g., existing) precision error (e.g., the existing precision error value) (new precision error >existing precision error), the processor 520 may determine that a less reliable offset has been acquired in an environment with magnetic disturbances. In the case that the new precision error (e.g., the new precision error value) is greater than the existing precision error (e.g., the existing precision error value) (new precision error>existing precision error), the processor 520 may not update the median value offset in the buffer used for the reference azimuth angle and may retain the previous (e.g., existing) median value offset. For example, the processor 520 may retain the previous (e.g., existing) accuracy level 1520 without updating the previous (e.g., existing) mid-value offset based on the previous (e.g., existing) mid-value offset in the case that the processor 520 determines that a less reliable offset has been acquired in an environment with magnetic disturbances. The processor 520 may then determine whether there is a gyro movement. In the case that there is a gyro movement, the processor 520 may acquire (e.g., generate) a new reference azimuth angle by compensating for the amount of gyro movement with the previous (e.g., existing) reference azimuth angle value.

In the case that, as a result of the comparison of the precision errors, the new precision error (e.g., the new precision error value) is less than or equal to the previous (e.g., the existing) precision error (e.g., the existing precision error value) (new precision error≤ existing precision error), the processor 520 may determine that a more reliable offset has been acquired in an environment with less magnetic disturbance. The processor 520 may update the offset to be used in the reference azimuth angle calculation with the newly acquired mid-value offset. The processor 520 may store the newly acquired median value offset in the memory 530. For example, the processor 520 may update the accuracy level 1520 based on the previous (e.g., existing) mid-value offset to a new accuracy level 1530 based on the newly acquired mid-value offset in the case that the processor 520 determines that a more reliable offset has been acquired in a low magnetic disturbance environment.

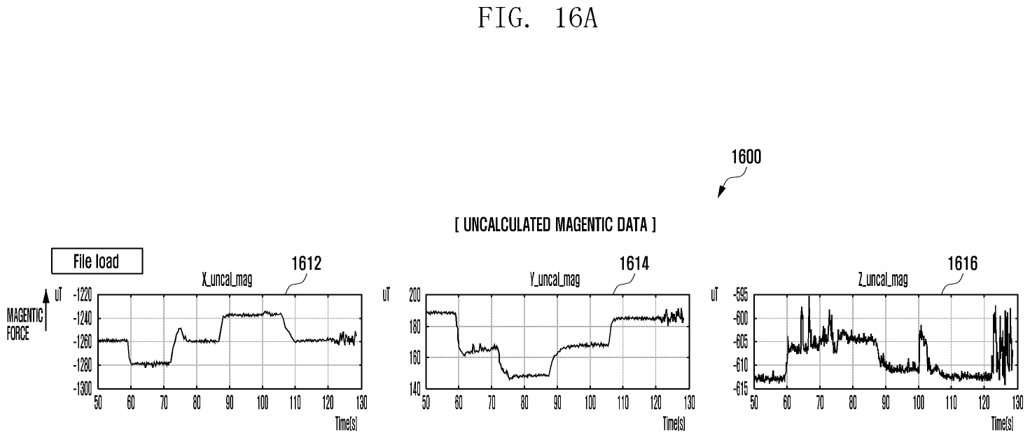

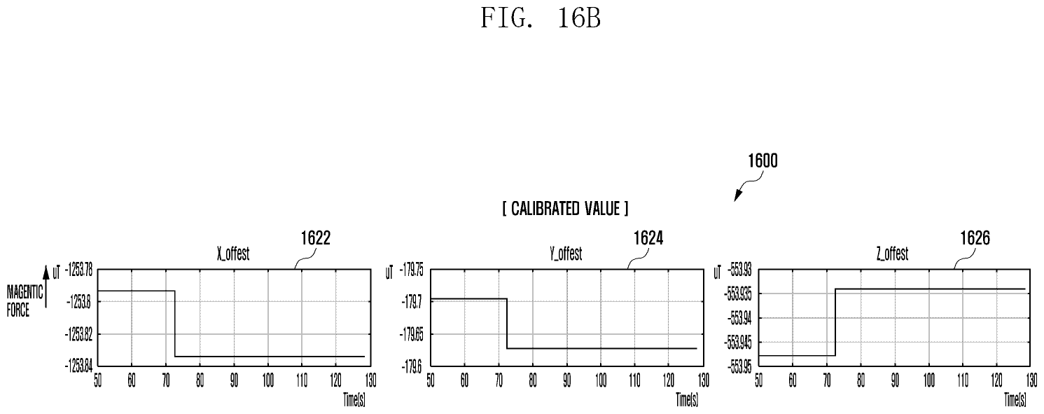

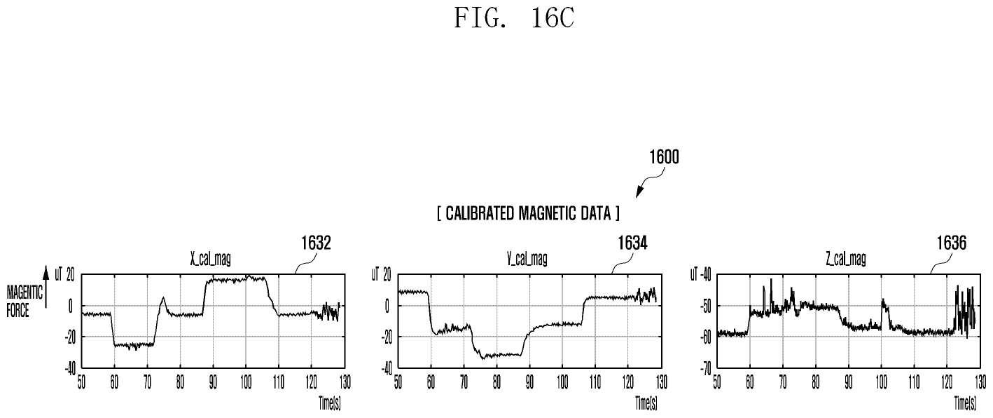

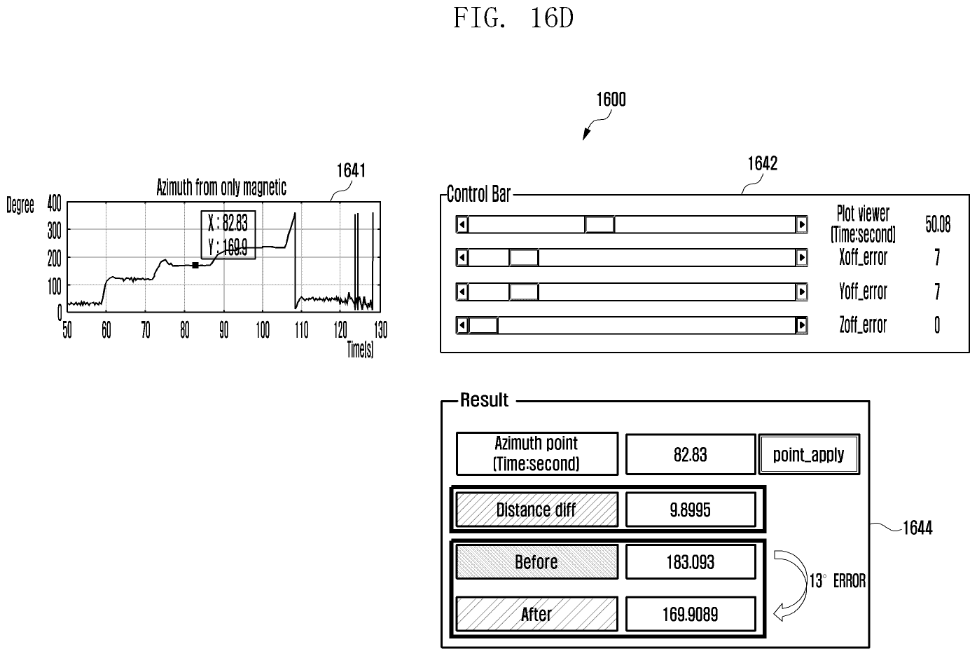

FIGS. 16A, 16B, 16C, and 16D are diagrams 1600 illustrating examples of simulating azimuth angle error according to a precision error level according to various embodiments of the disclosure.

For example, FIG. 16A illustrates uncalibrated magnetic data. FIG. 16B illustrates calibrated values. FIG. 16C illustrates calibrated magnetic data (e.g., resulting value from subtracting the value in FIG. 16B from the value in FIG. 16A). In FIGS. 16A to 16C, the horizontal axis (e.g., x-axis) may represent the number of samples logged, which can be matched by time (T: sec). 1 means 1 second per sample, so “130” may mean 130 seconds. The vertical axis (e.g., y-axis) may represent magnetic force (e.g., micro-tesla (μT)).

Referring to FIG. 16A, the processor (e.g., the processor 120 of FIG. 1, the processor 520 of FIG. 5) may acquire an uncalibrated raw data value 1612 for the x-axis, an uncalibrated raw data value 1614 for the y-axis, and an uncalibrated raw data value 1616 for the z-axis. The processor 520 may display the uncalibrated raw data value 1612 for the x-axis, the uncalibrated raw data value 1614 for the y-axis, and the uncalibrated raw data value 1616 for the z-axis on a display (e.g., the display 470 of FIG. 4A, the display 562 of FIG. 5) through a UI.

Referring to FIG. 16B, the processor (e.g., the processor 120 of FIG. 1, the processor 520 of FIG. 5) may acquire a calibrated offset value 1622 for the x-axis, a calibrated offset value 1624 for the y-axis, and a calibrated offset value 1626 for the z-axis. The processor 520 may display the calibrated offset value 1622 for the x-axis, the calibrated offset value 1624 for the y-axis, and the calibrated offset value 1626 for the z-axis on a display (e.g., the display 470 of FIG. 4A, the display 562 of FIG. 5) through a UI.

Referring to FIG. 16C, the processor (e.g., the processor 120 of FIG. 1, the processor 520 of FIG. 5) may acquire a calibration value 1632 for the x-axis that reflects a calibrated offset value 1622 for the x-axis to an uncalibrated raw data value 1612 for the x-axis. The processor (e.g., the processor 120 of FIG. 1, the processor 520 of FIG. 5) may acquire a calibration value 1634 for the y-axis that reflects a calibrated offset value 1624 for the y-axis to an uncalibrated raw data value 1614 for the y-axis. The processor (e.g., the processor 120 of FIG. 1, the processor 520 of FIG. 5) may acquire a calibration value 1636 for the z-axis that reflects a calibrated offset value 1626 for the z-axis to an uncalibrated raw data value 1616 for the z-axis. The processor (e.g., the processor 120 of FIG. 1, the processor 520 of FIG. 5) may display the calibration value 1632 for the x-axis, the calibration value 1634 for the y-axis, and the calibration value 1636 for the z-axis on a display (e.g., the display 470 of FIG. 4A, the display 562 of FIG. 5) through a UI.

Referring to FIG. 16D, in a graph 1641 of FIG. 16D, the horizontal axis (e.g., x-axis) may represent time in seconds, and the vertical axis (e.g., y-axis) may represent azimuth angle in degrees. For example, the azimuth angle may be represented as about 360 (0) degrees north, about 90 degrees east, about 180 degrees south, and about 270 degrees west.

For example, the processor (e.g., the processor 120 of FIG. 1, the processor 520 of FIG. 5) may display a control bar 1642 on the display (e.g., the display 470 of FIG. 4A, the display 562 of FIG. 5) through a UI.

For example, the control bar 1642 may represent a variable that allows the x-axis coordinate to be changed in order to determine how much azimuth angle variation occurs in the azimuth angle data at a particular time. Similarly, the y-axis or z-axis coordinates may be changed using the control bar 1642.

For example, Xoff_error, Yoff_error, Zoff_error means that the precision error is randomly generated by giving an offset error relative to the respective calibration value (initial value) of the sensor data (e.g., meaning 7 uT=Xoff_error=7). In the case of a precision error, the result, i.e., the azimuth angle error, may be simulated to show how much the error occurs.

For example, when an error of 7 uT in the X and Y axes is arbitrarily created compared to the existing calibration value for about 82.83 seconds, the precision error may be about 9.8995, which is the distance between two points. Depending on the corresponding precision error, the azimuth angle error would be from about 183 degrees to about 169.9 degrees, which means that an error of about 13° could be generated.

As described with reference to FIG. 10, the processor (e.g., the processor 120 of FIG. 1, the processor 520 of FIG. 5) may configure (or specify) as a precision error the largest value (max) of a distance (e.g., 1+2+ . . . +(N−2)+(N−1) distances) between the plurality of points (e.g., the plurality of points 1014 of FIG. 10) and a reference point (e.g., the reference point 1012 of FIG. 10). The processor 540 may display the precision error values for the x-axis, y-axis, and z-axis through the control bar 1642. The user may adjust (e.g., move left or right) the control bar 1642 to configure the precision error values for the x-axis, y-axis, and z-axis to any value (e.g., x-axis=7, y-axis=7, z-axis=0). The processor (e.g., the processor 120 of FIG. 1, the processor 520 of FIG. 5) may display the before and after updated azimuth angle result values 1644 on a display (e.g., the display 470 of FIG. 4A, the display 562 of FIG. 5) through a UI. For example, the processor 520 may display (e.g., Before=183.093, After=169.9089) in a display (e.g., the display 470 of FIG. 4A, the display 562 of FIG. 5) through a UI by reflecting an azimuth angle error (e.g., After=169.9089) determined as a precision error to the reference azimuth angle (e.g., Before=183.093) calculated based on an intermediate value offset.

According to one embodiment of the disclosure, the user may be made aware through the UI of the additional compensated azimuth angle error, allowing the user to more intuitively determine how accurate the current azimuth angle is. The processor 520 may display an additional calibration selection menu on the display (e.g., the display 470 of FIG. 4A, the display 562 of FIG. 5) through the UI to optionally perform additional calibration in the case that the azimuth angle error is large.

According to one embodiment of the disclosure, the operations illustrated in FIGS. 8 to 15, 16A, 16B, 16C, and 16D may be performed in a processor (e.g., the processor 120 of FIG. 1, the processor 520 of FIG. 5) of the electronic device 101, 200, 300, 400, and 500 (e.g., wearable electronic device, smart watch). For example, the memory (e.g., the memory 130 of FIG. 1, the memory 530 of FIG. 5) of the electronic device 101, 200, 300, 400, and 500 (e.g., wearable electronic device, smart watch) may include instructions that, when executed by the processor 120 and 520, allow the processor 120 and 520 to perform at least some of the operations illustrated in FIGS. 8 to 15 and 16A to 16D.

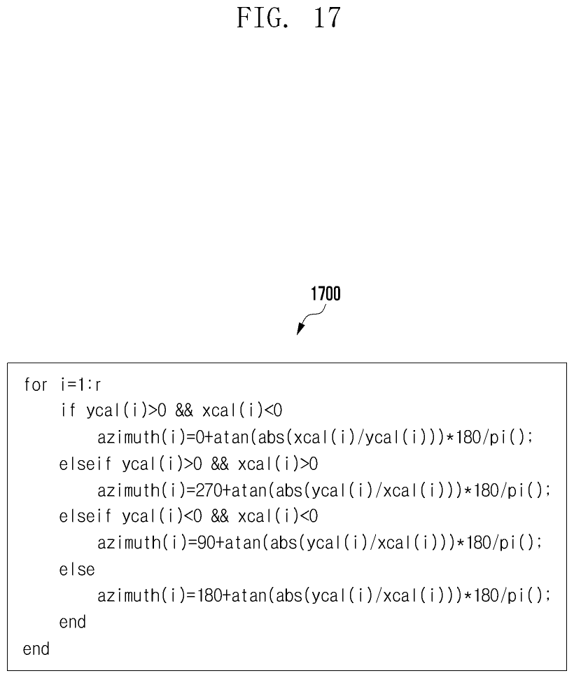

FIG. 17 is a diagram illustrating calculating azimuth angle based on pure magnetic data according to an embodiment of the disclosure.

Referring to FIG. 17, the memory (e.g., the memory 130 of FIG. 1, the memory 530 of FIG. 5) may include instructions for performing the equations illustrated in FIG. 17. The processor (e.g., the processor 120 of FIG. 1, the processor 520 of FIG. 5) may calculate an offset based on the calibration and compensate for the offset using the equations illustrated in FIG. 17. The processor 520 may compensate for the offset and calculate the offset using only the calibrated magnetic data. The processor 520 may calculate an azimuth angle error based on the precision error.

According to one embodiment of the disclosure, the operations illustrated in FIG. 17 may be performed in a processor (e.g., the processor 120 of FIG. 1, the processor 520 of FIG. 5) of the electronic device 101, 200, 300, 400, and 500 (e.g., wearable electronic device, smart watch). For example, the memory (e.g., the memory 130 of FIG. 1, the memory 530 of FIG. 5) of the electronic device 101, 200, 300, 400, and 500 (e.g., wearable electronic device, smart watch) may include instructions that, when executed by the processor 120 and 520, allow the processor 120 and 520 to perform at least some of the operations illustrated in FIG. 17.

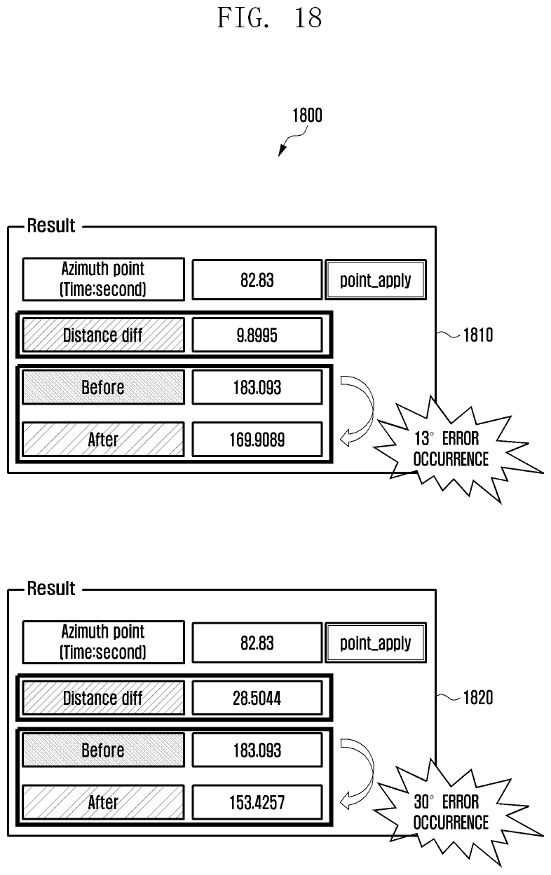

FIG. 18 is a diagram 1800 illustrating adjusting an azimuth angle error based on a precision error according to an embodiment of the disclosure.

Referring to FIG. 18, the processor (e.g., the processor 120 of FIG. 1, the processor 520 of FIG. 5) may display on a display (e.g., the display 470 of FIG. 4A, the display 562 of FIG. 5) through UI an azimuth angle error when applying a previous (e.g., existing) reference azimuth angle and an azimuth angle error when applying a new reference azimuth angle (e.g., an azimuth angle reflecting a precision error).

For example, in the case that there is an azimuth angle error of about 13 degrees between the azimuth angle error when applying the previous (e.g., existing) reference azimuth angle and the azimuth angle error when applying the new reference azimuth angle (e.g., an azimuth angle that reflects a precision error), information about the azimuth angle error 1810 may be displayed on a display (e.g., the display 470 of FIG. 4A, the display 562 of FIG. 5) through a UI.

For example, in the case that there is an azimuth angle error of about 30 degrees between the azimuth angle error when applying the previous (e.g., existing) reference azimuth angle and the azimuth angle error when applying the new reference azimuth angle (e.g., an azimuth angle that reflects a precision error), information about the azimuth angle error 1820 may be displayed on a display (e.g., the display 470 of FIG. 4A, the display 562 of FIG. 5) through a UI.

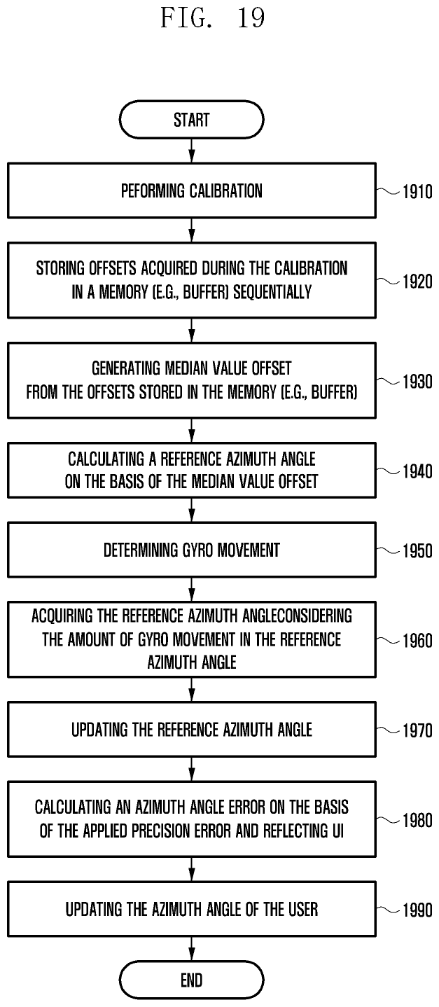

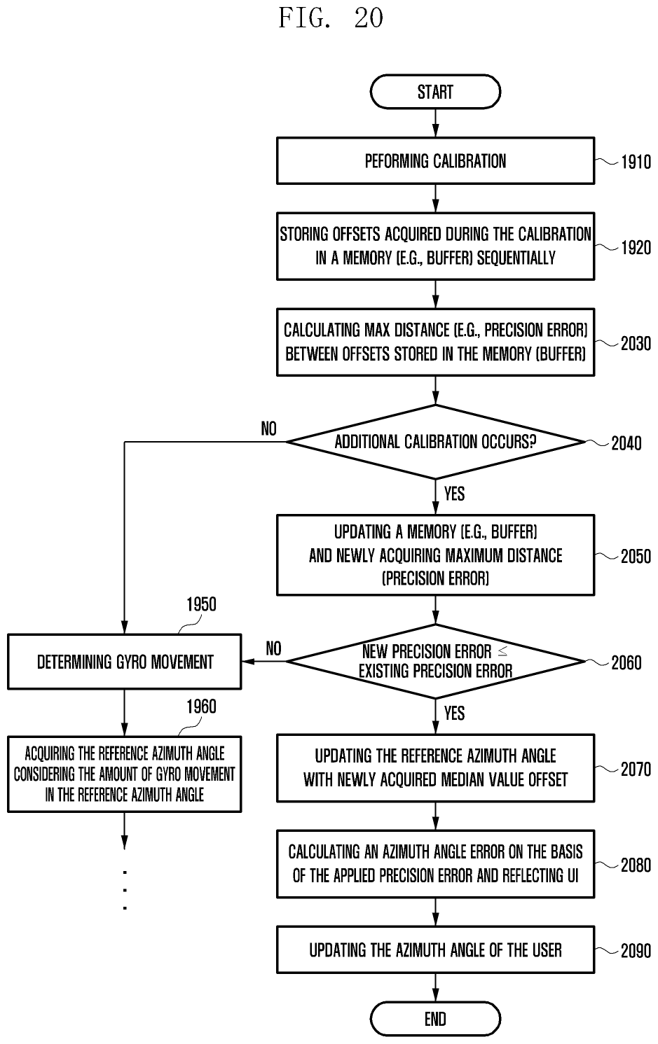

FIGS. 19 and 20 are flowcharts illustrating a method performed by an electronic device according to various embodiments of the disclosure.

In the following embodiments of the disclosure, each operation may be performed sequentially, but need not to be performed sequentially. For example, the order of the operations may be reversed, and at least two operations may be performed in parallel.

According to one embodiment of the disclosure, it may be understood that operations 1910 through 2090 are performed on a processor (e.g., the processor 120 of FIG. 1, the processor 520 of FIG. 5) of an electronic device 500 (e.g., the electronic device 101 of FIG. 1, the electronic device 200 of FIG. 2A, the electronic device 300 of FIG. 3A, the electronic device 400 of FIGS. 4A and 4B).

Referring to FIG. 19, in 1910, a calibration of an azimuth angle may be performed to perform a compass function of an electronic device (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5). For example, a user may perform the calibration by moving the electronic device 101, 200, 300, 400, and 500 in a figure of 8 (or a 360-degree rotation). For example, the calibration may be performed for a period of time (from about 5 seconds to about 10 seconds).

In operation 1920, the geomagnetic sensor (e.g., the geomagnetic sensor 700 of FIG. 7) may acquire magnetic data (e.g., the magnetic data 910 of FIG. 9) for the three axes (e.g., the x-axis, y-axis, and z-axis) during the calibration operation. The geomagnetic sensor 700 may provide the acquired offsets (e.g., magnetic data) to the processor 520 (e.g., the processor 120 of FIG. 1). The processor 520 may store the plurality of offsets (e.g., offset1, offset2, - - - , offsetN) (e.g., magnetic data) acquired during the calibration in memory 530 (e.g., the memory 130 of FIG. 1).

For example, performing the calibration of the azimuth angle may result in a plurality of offsets (e.g., offset1, offset2, - - - , offsetN) that estimate the magnetic offset inside the housing of the electronic device 101, 200, 300, 400, and 500 excluding the Earth's magnetic field. The processor 520 may update the plurality of offsets (e.g., offset1, offset2, - - - , offsetN).

For example, the memory 530 may include a plurality of buffers (e.g., N buffers). The processor 520 may store N offsets (e.g., offset1, offset2, - - - , offsetN) in the plurality of buffers (e.g., N buffers).

In operation 1930, the processor 520 may acquire (e.g., generate) a median value offset (e.g., the median values 920 of FIG. 9) from the N offsets (e.g., offset1, offset2, - - - , offsetN) stored in the memory 530. The processor 520 may store the median value offset in the memory 530.

In operation 1940, the processor 520 may calculate (e.g., generate) a reference azimuth angle based on the median value offset.

In operation 1950, the processor 520 may determine whether there is a gyro movement. In the case that there is a gyro movement, the processor 520 may acquire the amount of gyro movement.

In operation 1960, the processor 520 may acquire the reference azimuth angle considering the amount of gyro movement in the reference azimuth angle. The processor 520 may store the generated reference azimuth angle in the memory 530. For example, the processor 520 may acquire (e.g., generate) a new reference azimuth angle by compensating for the amount of gyro movement with the previous (e.g., existing) reference azimuth angle value. The processor 520 may store the new reference azimuth angle in the memory 530.

For example, for azimuth angle, the absolute amount of rotation may be recognized, and for gyro, the relative amount of rotation may be recognized. In the case that no further calibration occurs, or the newly acquired precision is greater than the existing precision, the reference azimuth angle information may be updated by compensating for the gyro rotation (rotation that is not affected by the magnetic force) with the azimuth angle information calculated from the previously acquired calibration values. The processor 120 and 520 may determine that there is no newly acquired calibration value, or that the newly acquired calibration value is a less reliable calibration value acquired in the presence of magnetic disturbances. In the case that the processor 120 and 520 determines that there is no newly acquired calibration value, or that the newly acquired calibration value is a less reliable calibration value acquired in the presence of magnetic disturbances, the processor 120 and 520 may compensate the existing azumuth information with a relative rotation amount calculated from a gyro sensor value that is insensitive to magnetic forces (e.g., existing azimuth angle+relative rotation amount).

In operation 1970, the processor 520 may update the previous (e.g., existing) reference azimuth angle with the new reference azimuth angle.

In operation 1980, the processor 520 may calculate an azimuth angle error based on the previous (e.g., existing) applied precision error. The processor 520 may display the azimuth angle error on a display (e.g., the display 470 of FIG. 4A, the display 562 of FIG. 5) through a UI.

In operation 1990, the processor 520 may acquire (e.g., generate) a new azimuth angle by reflecting the azimuth angle error acquired in operation 1980 to a previous (e.g., existing) reference azimuth angle. For example, the processor 520 may display the azimuth angle error because of the magnetic disturbance on a display (e.g., the display 470 of FIG. 4A, the display 562 of FIG. 5) through a UI. For example, the processor 520 may display a new azimuth angle with the azimuth angle error corrected on the display (e.g., the display 470 of FIG. 4A, the display 562 of FIG. 5) through a UI. For example, the processor 520 may display the azimuth angle error because of the magnetic disturbance and the new azimuth angle with the azimuth angle corrected on a display (e.g., the display 470 of FIG. 4A, the display 562 of FIG. 5) through a UI.

Referring to FIG. 20, in 1910, a calibration of an azimuth angle may be performed to execute a compass function of an electronic device (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5). For example, a user may perform the calibration by moving the electronic device 101, 200, 300, 400, and 500 in a figure of 8 (or a 360-degree rotation). For example, the calibration may be performed for a period of time (from about 5 seconds to about 10 seconds).

In operation 1920, the geomagnetic sensor (e.g., the geomagnetic sensor 700 of FIG. 7) may acquire magnetic data (e.g., the magnetic data 910 of FIG. 9) for three axes (e.g., the x-axis, y-axis, and z-axis) during the calibration operation. The geomagnetic sensor 700 may provide the acquired offsets (e.g., magnetic data) to the processor 520 (e.g., the processor 120 of FIG. 1). The processor 520 may store the plurality of offsets (e.g., offset1, offset2, - - - , offsetN) (e.g., magnetic data) acquired during the calibration in the memory 530 (e.g., the memory 130 in FIG. 1).

For example, performing a calibration of azimuth angle may generate a plurality of offsets (e.g., offset1, offset2, - - - , offsetN) that estimate a magnetic offset inside the housing of the electronic device 101, 200, 300, 400, and 500 excluding the Earth's magnetic field.

In operation 2030, the processor 520 may calculate a max distance (e.g., precision error) between the N offsets (e.g., offset1, offset2, - - - , offsetN) stored in the memory 530.

In operation 2040, the processor 520 may determine whether additional calibrations have occurred.

In the case that, as a result of the determination in operation 2040, additional calibrations have not occurred, operation 1950 illustrated in FIG. 19 may be performed. For example, in the case that no additional calibration has occurred, the processor 120 and 520 may generate new reference azimuth angle information by reflecting the amount of gyro movement (e.g., reference azimuth angle+gyro movement) in the reference azimuth angle calculated as the median offset. The processor 120 and 520 may display the new reference azimuth angle information on a display to provide the new reference azimuth angle information to a user.

In operation 1950 illustrated in FIG. 19, the processor 520 may determine whether there is a gyro movement. The processor 520 may acquire the amount of gyro movement in the case that there is a gyro movement.

In operation 1960, the processor 520 may acquire the reference azimuth angle considering the amount of gyro movement in the reference azimuth angle. The processor 520 may store the generated reference azimuth angle in the memory 530. For example, the processor 520 may acquire (e.g., generate) a new reference azimuth angle by compensating for the amount of gyro movement with the previous (e.g., existing) reference azimuth angle value. The processor 520 may store the new reference azimuth angle in the memory 530.

The processor 520 may then perform operation 1970 through operation 1990.

In the case that, as a result of the determination in operation 2040, additional calibrations have occurred, the processor 520 may perform operation 2050.

In operation 2050, the processor 520 may update a plurality of offsets (e.g., offset1, offset2, - - - , offsetN). For example, the memory 530 may include a plurality of buffers (e.g., N buffers). The processor 520 may store the N offsets (e.g., offset1, offset2, - - - , offsetN) in the plurality of buffers (e.g., N buffers). For example, a maximum distance between the offsets (e.g., a precision error) may be acquired (e.g., generated). The processor 520 may store the max distance between the offsets (e.g., the precision error) in the memory 530.

In operation 2060, the processor 520 may compare the new precision error to a previous (e.g., existing) precision error.

In the case that, as a result of the determination of operation 2060, the new precision error is not less than or equal to the previous (e.g., existing) precision (NO), the processor 520 may perform operations 1950 through 1990.

In the case that, as a result of the determination of operation 2060, the new precision error is less than or equal to the previous (e.g., existing) precision (YES), the processor 520 may perform operation 2070.

In operation 2070, the processor 520 may acquire a new median value offset. The processor 520 may acquire (e.g., generate) a new reference azimuth angle by applying the new median value offset to the previous (e.g., existing) reference azimuth angle. The processor 520 may update the previous (e.g., existing) reference azimuth angle with the new reference azimuth angle, replacing the previous (e.g., existing) reference azimuth angle.

In operation 2080, the processor 520 may calculate an azimuth angle error based on the new precision error. The processor 520 may acquire an azimuth angle based on the azimuth angle error. For example, the processor 520 may display the azimuth angle error because of the magnetic disturbance on a display (e.g., the display 470 of FIG. 4A, the display 562 of FIG. 5) through a UI.

In operation 2090, the processor 520 may acquire (e.g., generate) a new azimuth angle by considering the azimuth angle error acquired in operation 2080 to a previous (e.g., existing) reference azimuth angle. For example, the processor 520 may update the new azimuth angle by replacing the previous (e.g., existing) azimuth angle.

According to one embodiment of the disclosure, the processor 520 may perform the operations 1910-1990 of FIG. 19 and the operations 1910, 1920, 1950, 1960, and 2030-2090 of FIG. 20 simultaneously.

According to one embodiment of the disclosure, the processor 520 may perform the operations 1910-1990 of FIG. 19 and the operations 1910, 1920, 1950, 1960, and 2030-2090 of FIG. 20 sequentially.

According to one embodiment of the disclosure, the processor 520 may perform the operations 1910-1990 of FIG. 19 and the operations 1910, 1920, 1950, 1960, and 2030-2090 of FIG. 20 in parallel.

According to one embodiment of the disclosure, the operations of FIGS. 19 and 20 may be performed on a processor (e.g., the processor 120 of FIG. 1, the processor 520 of FIG. 5) of the electronic device 101, 200, 300, 400, and 500 (e.g., wearable electronic device, smart watch). For example, the memory of the electronic device 101, 200, 300, 400, and 500 (e.g., wearable electronic device, smart watch) (e.g., the memory 130 of FIG. 1, the memory 530 of FIG. 5) may include instructions that, when executed by the processor 120 and 520, enable the processor 120 and 520 to perform at least some of the operations illustrated in FIGS. 19 and 20.

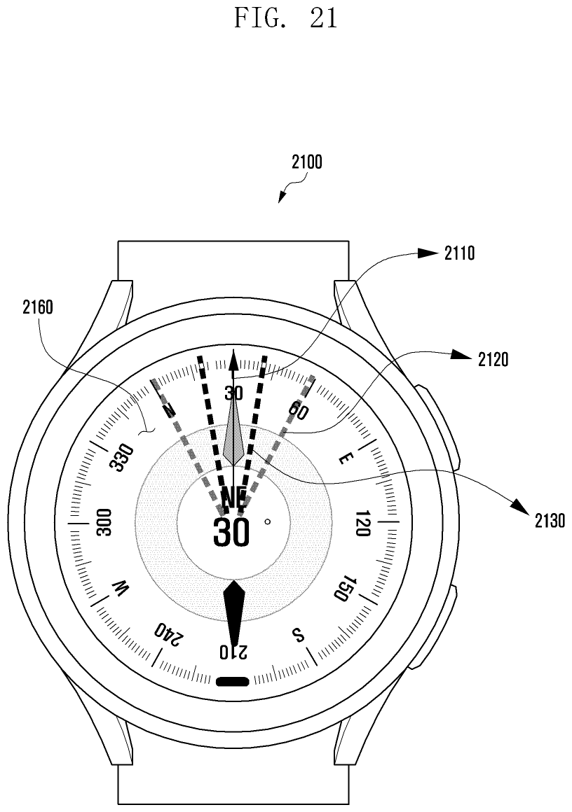

FIG. 21 is a diagram 2100 illustrating dynamically displaying an azimuth angle error according to a precision error level according to an embodiment of the disclosure.

Referring to FIG. 21, according to one embodiment of the disclosure, the processor (e.g., the processor 520 of FIG. 5) may display the new azimuth angle with the azimuth angle error corrected on a display 2160 (e.g., the display 470 of FIG. 4A, the display 562 of FIG. 5) through the UI. For example, the processor 520 may display the error in the azimuth angle because of the magnetic disturbance and the new azimuth angle with the azimuth angle corrected on the display 2160 (e.g., the display 470 of FIG. 4A, the display 562 of FIG. 5) through the UI.

According to one embodiment of the disclosure, the processor (e.g., the processor 120 of FIG. 1, the processor 520 of FIG. 5) may acquire an median value offset among the offsets stored in the memory (e.g., the memory 130 of FIG. 1, the memory 530 of FIG. 5) to display the reference azimuth angle 2110 on the display 2160 (e.g., the display 470 of FIG. 4A, the display 562 of FIG. 5) through the UI.

According to one embodiment of the disclosure, the processor 120 and 520 may display the azimuth angle errors 2120 and 2130 on the display 2160 (e.g., the display 470 of FIG. 4A, the display 562 of FIG. 5) through the UI by adding the azimuth angle errors to the angle of view (+angle, −angle) based on the precision error.

For example, the processor 120 and 520 may display the azimuth angle error 2120 (e.g., about ±30 degrees of azimuth angle error) relative to the previous (e.g., existing) reference azimuth angle on the display 2160 (e.g., the display 470 of FIG. 4A, the display 562 of FIG. 5) through the UI in the form of an angle of view.

For example, the processor 120 and 520 may display the azimuth angle error 2130 (e.g., about ±13 degrees of azimuth angle error) based on the updated new reference azimuth angle on the display 2160 (e.g., the display 470 of FIG. 4A, the display 562 of FIG. 5) through the UI in the form of an angle of view.

For example, after updating the reference azimuth angle, the processor 120 and 520 may perform the operations 1980 and 1990 of FIG. 19 to calculate an azimuth angle error based on the applied precision error, and display the calculated azimuth angle error to the user through the UI. At this time, a range of azimuth angles (e.g., a fan-shaped angle display) may be UI displayed on the display 2160 based on the azimuth angle error. The processor 120 and 520 may iterate over the azimuth angle error at each update point of the azimuth angle to compensate for the range of the azimuth angle (e.g., the fan-shaped angle display) and display it through the display 2160.

For example, after updating the reference azimuth angle with the newly acquired median value offset, the processor 120 and 520 may perform the operations 2080 and 2090 of FIG. 20 to calculate an azimuth angle error based on the applied precision error, and display the calculated azimuth angle error to the user through the UI. At this time, a range of azimuth angles (e.g., a fan-shaped angle display) may be UI displayed on the display 2160 based on the azimuth angle error. The processor 120 and 520 may iterate over the azimuth angle error at each update time of the azimuth angle to compensate for the range of the azimuth angle (e.g., the fan-shaped angle display) and display it through the display 2160.

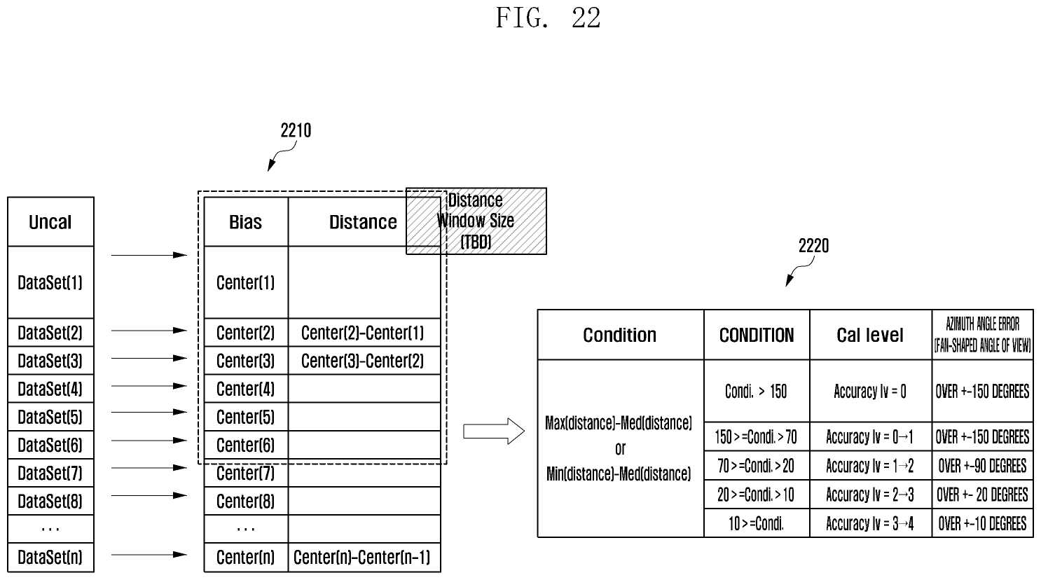

FIG. 22 is a diagram illustrating calibration result values according to precision error and confidence level at each stage according to an embodiment of the disclosure.

Referring to FIG. 22, a processor (e.g., the processor 120 of FIG. 1, the processor 520 of FIG. 5) may calculate a calibration result value based on a precision error. The processor 120 and 520 may acquire a median value 2210 (e.g., a center value) of N offsets (e.g., offset1, offset2, - - - , offsetN). The processor 120 and 520 may calculate (e.g., generate) a new reference azimuth angle based on the median value 2210 (e.g., the center value) of the N offsets (e.g., offset1, offset2, - - - , offsetN).

According to one embodiment of the disclosure, the processor 120 and 520 may categorize a confidence level 2220 for the resulting value of the calibration into a certain level (e.g., step 0 to step 5) (or level 0 to level 5).

For example, the processor 120 and 520 may categorize the confidence level 2220 based on the azimuth angle error relative to the previous (e.g., existing) reference azimuth angle into a certain level (e.g., step 0 to step 5) (or level 0 to level 5). The processor 120 and 520 may display the categorized confidence levels 2220 (e.g., confidence levels based on a previous (e.g., existing reference azimuth angle) on a display 2160 (e.g., the display 470 of FIG. 4A, the display 562 of FIG. 5) through a UI.

For example, the processor 120 and 520 may categorize the confidence level 2220 based on the azimuth angle error relative to the new reference azimuth angle into a certain level (e.g., step 0 to step 5) (or level 0 to level 5). The processor 120 and 520 may display the categorized confidence levels 2220 (e.g., confidence levels based on the new reference azimuth angle) on a display 2160 (e.g., the display 470 of FIG. 4A, the display 562 of FIG. 5) through a UI.

A wearable electronic device (e.g., the electronic device 101 of FIG. 1, the electronic device 200 of FIG. 2A, the electronic device 300 of FIG. 3A, the electronic device 400 of FIGS. 4A and 4B, the electronic device 500 of FIG. 5) according to an embodiment of the disclosure may include a display (e.g., the display 470 of FIG. 4A, the display 562 of FIG. 5, the display 2160 of FIG. 21), a sensor for sensing geomagnetic fields to acquire geomagnetic data (e.g., the sensor module 176 of FIG. 1, the sensor 421 of FIG. 4B), a processor (e.g., the processor 120 of FIG. 1, the processor 520 of FIG. 5) that controls operation of the display 470, 562, and 2160 and the sensor 176 and 421, and acquires an azimuth angle based on the geomagnetic data, and memory (e.g., the memory 130 of FIG. 1, the memory 530 ( ) of FIG. 5) operatively coupled to the processor 120 and 520. During execution, the processor 120 and 520 may acquire a plurality of offsets based on the geomagnetic data during execution of the geomagnetic calibration. During execution, the processor 120 and 520 may acquire a reference azimuth angle based on the plurality of offsets. The processor 120 and 520 may, during execution, acquire an azimuth angle error based on a uniformity of the plurality of offsets. During execution, the processor 120 and 520 may compensate for the azimuth angle error with the reference azimuth angle to acquire a new reference azimuth angle. During execution, the processor 120 and 520 may update the memory 130 and 530 with the new reference azimuth angle.

According to one embodiment of the disclosure, the processor 120 and 520 may, during execution, display the first azimuth angle error relative to the reference azimuth angle on the displays 470, 562, and 2160 through a user interface.

According to one embodiment of the disclosure, the processor 120 and 520 may, during execution, display a second azimuth angle error according to the new azimuth angle on the display 470, 562, and 2160 through a user interface.

According to one embodiment of the disclosure, the processor 120 and 520 may, during execution, display on the display 470, 562, and 2160 a comparison of a first azimuth angle error according to the reference azimuth angle and a second azimuth angle error according to the new azimuth angle.

According to one embodiment of the disclosure, the processor 120 and 520 may, during execution, acquire a median value offset among the plurality of offsets. During execution, the processor 120 and 520 may calculate the reference azimuth angle based on the median value offset.

According to one embodiment of the disclosure, the sensor 176 and 421 may acquire the amount of gyro movement of the electronic device 101, 200, 300, 400, and 500. During execution, the processor 120 and 520 may compensate for the amount of gyro movement with the reference azimuth angle to acquire the new azimuth angle.

According to one embodiment of the disclosure, the processor 120 and 520 may, during execution, acquire a first precision error based on a maximum distance between the plurality of first offsets acquired by executing the first calibration. The processor 120 and 520 may, during execution, acquire a second precision error based on a maximum distance between the plurality of second offsets acquired by executing the second calibration. During execution, the processor 120 and 520 may update the azimuth angle by comparing the first precision error with the second precision error.

According to one embodiment of the disclosure, the processor 120 and 520 may, during execution, retain a previously acquired reference azimuth angle in the case that the second precision error is greater than the first precision error.

According to one embodiment of the disclosure, the processor 120 and 520 may, during execution, acquire a new median value offset from among the plurality of second offsets in the case that the first precision error is less than or equal to the second precision error. During execution, the processor 120 and 520 may acquire a new reference azimuth angle based on the new median value offset.

According to one embodiment of the disclosure, the processor 120 and 520 may, during execution time, update the new azimuth angle to memory 130 and 530. During execution, the processor 120 and 520 may display the new azimuth angle on the display 470, 562, and 2160.

In a method performed by an electronic device 101, 200, 300, 400, and 500 according to an embodiment of the disclosure, wherein the electronic device 101, 200, 300, 400, and 500 comprises a sensor configured to detect geomagnetism, the processor 120 and 520 of the electronic device 101, 200, 300, 400, and 500 may acquire geomagnetic data upon execution of a geomagnetic calibration. Based on the geomagnetic data, a plurality of offsets may be acquired. A reference azimuth angle may be acquired based on the plurality of offsets. An azimuth angle error may be acquired based on a uniformity of the plurality of offsets. A new reference azimuth angle may be acquired by compensating for the azimuth angle error with the reference azimuth angle. The new reference azimuth angle may be updated on the memory 130 and 530.

According to one embodiment of the disclosure, the processor 120 and 520 may display the first azimuth angle error relative to the reference azimuth angle on a display 470, 562, and 2160 of the electronic device 101, 200, 300, 400, and 500 through a user interface.

According to one embodiment of the disclosure, the processor 120 and 520 may display a second azimuth angle error according to the new azimuth angle on the display 470, 562, and 2160 of the electronic device 101, 200, 300, 400, and 500.

According to one embodiment of the disclosure, the processor 120 and 520 may display on the display 470, 562, and 2160 of the electronic device 101, 200, 300, 400, and 500 a comparison of the first azimuth angle error according to the reference azimuth angle and the second azimuth angle error according to the new azimuth angle.

According to one embodiment of the disclosure, the processors 120 and 520 may acquire a median value offset among the plurality of offsets. Based on the median value offset, the reference azimuth angle may be calculated.

According to one embodiment of the disclosure, the sensor 176 and 421 may acquire the amount of gyro movement of the electronic device 101, 200, 300, 400, and 500. The processor 120 and 520 may compensate for the amount of gyro movement with the reference azimuth angle to acquire the new azimuth angle.

According to one embodiment of the disclosure, the processor 120 and 520 may acquire a first precision error based on a maximum distance between the plurality of first offsets acquired by executing the first calibration. The processor 120 and 520 may acquire a second precision error based on a maximum distance between the plurality of second offsets acquired by executing the second calibration. The processor 120 and 520 may update the azimuth angle by comparing the first precision error with the second precision error.

According to one embodiment of the disclosure, the processor 120 and 520 may retain a previously acquired reference azimuth angle in the case that the second precision error is greater than the first precision error.

According to one embodiment of the disclosure, the processor 120 and 520 may acquire a new median value offset from among the plurality of second offsets in the case that the first precision error is less than or equal to the second precision error. The processor 120, 520 may acquire a new reference azimuth angle based on the new median value offset.

According to one embodiment of the disclosure, the processor 120 and 520 may update the new azimuth angle to the memory 130 and 530 of the electronic device 101, 200, 300, 400, and 500. The processor 120 and 520 may display the new azimuth angle on a display 470, 562, and 2160 of the electronic device 101, 200, 300, 400, and 500.

The electronic device and the method of operation thereof according to one embodiment of the disclosure may naturally induce magnetic data correction and may provide accurate azimuth angle information to a user even in magnetic disturbance environments.

The electronic device and the method of operation thereof according to an embodiment of the disclosure may determine the error level of the currently used azimuth angle information and provide the error level of the azimuth angle information to the user.

The electronic device and the method of operation thereof according to one embodiment of the disclosure may improve the accuracy of azimuth angle in an environment (outdoor, indoor, vehicle) where magnetic disturbances occur.

The electronic device and the method of operation thereof according to one embodiment of the disclosure may improve the accuracy of an azimuth angle in an environment where magnetic disturbances occur because of the electronic device (e.g., smartphone, wearable electronic device, smartwatch) being moved from indoors to outdoors.

The electronic device and the method of operation thereof according to one embodiment of the disclosure may improve the accuracy of an azimuth angle in an environment where magnetic disturbances occur because of the electronic device (e.g., smartphone, wearable electronic device, smartwatch) being moved from outdoors to indoors.

The electronic device and the method of operation thereof according to one embodiment of the disclosure may improve the accuracy of an azimuth angle in an environment where magnetic disturbances occur because of the electronic device (e.g., smartphone, wearable electronic device, smartwatch) being moved from outside to inside a vehicle.

The electronic device and the method of operation thereof according to one embodiment of the disclosure may improve the accuracy of an azimuth angle in an environment where magnetic disturbances occur because of the electronic device (e.g., smartphone, wearable electronic device, smartwatch) being moved from inside a vehicle to outside.

The electronic device and the method of operation thereof according to one embodiment of the disclosure may improve the accuracy of an azimuth angle in an environment where magnetic disturbances occur because of the vehicle in which the electronic device (e.g., smartphone, wearable electronic device, smartwatch) is located moving from outdoors to indoors.

The electronic device and the method of operation thereof according to one embodiment of the disclosure may improve the accuracy of an azimuth angle in an environment where magnetic disturbances occur because of the vehicle in which the electronic device (e.g., smartphone, wearable electronic device, smartwatch) is located moving from indoors to outdoors.

The electronic device and the method of operation thereof according to one embodiment of the disclosure may compare a previous (e.g., existing) precision error with a newly acquired precision error, and selectively utilize the precision error acquired in an environment with low magnetic disturbance. The geomagnetic data based on the precision error acquired in the low magnetic disturbance environment may be used to update the azimuth angle to improve the accuracy of the azimuth angle. Further, the accuracy of the azimuth angle may be improved by optionally applying a gyro weighting along with the precision error.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities, and some of the multiple entities may be separately disposed in different components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wearable electronic device comprising:
a display;
a sensor configured to detect geomagnetism and acquire geomagnetic data;
memory storing one or more computer programs; and
one or more processors communicatively coupled to the display, the sensor, and the memory, wherein the one or more computer programs include computer-executable instructions that, when executed by the one or more processors individually or collectively, cause the wearable electronic device to:
acquire an azimuth angle based on the geomagnetic data,
acquire a plurality of offsets based on the geomagnetic data when geomagnetic calibration is executed,
acquire a reference azimuth angle based on the plurality of offsets,
acquire an azimuth angle error based on a uniformity of the plurality of offsets,
acquire a new reference azimuth angle by compensating for the azimuth angle error with the reference azimuth angle, and
update the new reference azimuth angle in the memory.

2. The wearable electronic device of claim 1, wherein the one or more computer programs further include computer-executable instructions that, when executed by the one or more processors individually or collectively, cause the wearable electronic device to, during execution, display a first azimuth angle error according to the reference azimuth angle on the display through a user interface.

3. The wearable electronic device of claim 2, wherein the one or more computer programs further include computer-executable instructions that, when executed by the one or more processors individually or collectively, cause the wearable electronic device to, during execution, display a second azimuth angle error according to the new azimuth angle on the display.

4. The wearable electronic device of claim 3, wherein the one or more computer programs further include computer-executable instructions that, when executed by the one or more processors individually or collectively, cause the wearable electronic device to, during execution, compare the first azimuth angle error according to the reference azimuth angle and the second azimuth angle error according to the new azimuth angle and displays it on the display.

5. The wearable electronic device of claim 1, wherein the one or more computer programs further include computer-executable instructions that, when executed by the one or more processors individually or collectively, cause the wearable electronic device to, during execution, acquire a median value offset among the plurality of offsets and calculates the reference azimuth angle based on the median value offset.

6. The wearable electronic device of claim 1,
wherein the sensor is further configured to acquire an amount of gyro movement of the wearable electronic device, and
wherein the one or more computer programs further include computer-executable instructions that, when executed by the one or more processors individually or collectively, cause the wearable electronic device to, during execution, acquire a new azimuth angle by compensating for the amount of gyro movement with the reference azimuth angle.

7. The wearable electronic device of claim 1, wherein the one or more computer programs further include computer-executable instructions that, when executed by the one or more processors individually or collectively, cause the wearable electronic device, during execution, to:
acquire a first precision error based on the maximum distance between a plurality of first offsets acquired by executing a first calibration,
acquire a second precision error based on the maximum distance between a plurality of second offsets acquired by executing a second calibration, and
update the azimuth angle by comparing the first precision error and the second precision error.

8. The wearable electronic device of claim 7, wherein the one or more computer programs further include computer-executable instructions that, when executed by the one or more processors individually or collectively, cause the wearable electronic device to, during execution, retain a previously acquired azimuth angle when the second precision error is larger than the first precision error.

9. The wearable electronic device of claim 7, wherein the one or more computer programs further include computer-executable instructions that, when executed by the one or more processors individually or collectively, cause the wearable electronic device, during execution, to:
acquire a new median value offset among the plurality of the second offsets, and
acquire a new reference azimuth angle based on the new median value, when the first precision error is less than or equal to the second precision error.

10. The wearable electronic device of claim 1, wherein the one or more computer programs further include computer-executable instructions that, when executed by the one or more processors individually or collectively, cause the wearable electronic device to, during execution, update the new azimuth angle in the memory and display the new azimuth angle on the display.

11. A method performed by an electronic device including a sensor configured to detect geomagnetism, the method comprising:
acquiring geomagnetic data when executing geomagnetic calibration;
acquiring a plurality of offsets based on the geomagnetic data;
acquiring a reference azimuth angle based on the plurality of offsets;
acquiring an azimuth angle error based on a uniformity of the plurality of offsets;
acquiring a new reference azimuth angle by compensating for the azimuth angle error with the reference azimuth angle; and
updating the new reference azimuth angle in memory of the electronic device storing one or more computer programs.

12. The method of claim 11, further comprising displaying a first azimuth angle error according to the reference azimuth angle on the display of the electronic device through a user interface.

13. The method of claim 12, further comprising displaying a second azimuth angle error according to the new azimuth angle on the display of the electronic device.

14. The method of claim 13, further comprising:
comparing the first azimuth angle error according to the reference azimuth angle with the second azimuth angle error according to the new azimuth angle; and
displaying it on the display of the electronic device.

15. The method of claim 11, further comprising;
acquiring a median value offset among the plurality of offsets; and
calculating the reference azimuth angle based on the median value offset.

16. The method of claim 11, wherein the sensor is further configured to:
acquire an amount of gyro movement of the electronic device, and
acquire the new azimuth angle by compensating for the amount of gyro movement with the reference azimuth angle.

17. The method of claim 16, further comprising:
acquiring a first precision error based on the maximum distance between a plurality of first offsets acquired by executing a first calibration;
acquiring a second precision error based on the maximum distance between a plurality of second offsets acquired by executing a second calibration; and
updating the azimuth angle by comparing the first precision error with the second precision error.

18. The method of claim 17, further comprising retaining a previously acquired reference azimuth angle when the second precision error is greater than the first precision error.

19. One or more non-transitory computer-readable storage media storing one or more computer programs including computer-executable instructions that, when executed by one or more processors of an electronic device including a sensor configured to detect geomagnetism individually or collectively, cause the electronic device to perform operations, the operations comprising:
acquiring geomagnetic data when executing geomagnetic calibration;
acquiring a plurality of offsets based on the geomagnetic data;
acquiring a reference azimuth angle based on the plurality of offsets;
acquiring an azimuth angle error based on a uniformity of the plurality of offsets;
acquiring a new reference azimuth angle by compensating for the azimuth angle error with the reference azimuth angle; and
updating the new reference azimuth angle in memory of the electronic device storing one or more computer programs.

20. The one or more non-transitory computer-readable storage media of claim 19, the operations further comprising:
displaying a first azimuth angle error according to the reference azimuth angle on the display of the electronic device through a user interface.
